(19) United States
(12) Patent Application Publication
(10) Pub. No.: US 2006/0038554 A1
(43) Pub. Date: Feb. 23, 2006

(54) Electron beam test system stage

(75) Inventors: Shinichi Kurita, San Jose, CA (US); Emanuel Beer, San Jose, CA (US); Hung T. Nguyen, Fremont, CA (US); Benjamin Johnston, Los Gatos, CA (US); Fayez Abboud, Pleasanton, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/190,320

(22) Filed: Jul. 27, 2005

Related U.S. Application Data
(63) Continuation-in-part of application No. 11/018,236, filed on Dec. 21, 2004.
(63) Continuation-in-part of application No. 11/018,236, filed on Dec. 21, 2004.
Application No. 11/018,236 is a division of application No. 10/778,982, filed on Feb. 12, 2004, now Pat. No. 6,833,717.
(60) Provisional application No. 60/592,668, filed on Jul. 30, 2004.

(51) Int. Cl. G01R 31/28

(52) U.S. Cl. 324/158.1

(57) ABSTRACT

A method and integrated system for electron beam testing a substrate is provided. In one aspect, the integrated system includes an electron beam testing chamber having a substrate table disposed therein. The substrate table is capable of moving a substrate within the testing chamber in both horizontal and vertical directions. The system also includes a load lock chamber disposed adjacent a first side of the testing chamber, and a prober storage assembly disposed beneath the testing chamber. A prober transfer assembly is disposed adjacent a second side of the testing chamber and arranged to transfer one or more probers between the prober storage assembly and the testing chamber. Further, one or more electron beam testing devices are disposed on an upper surface of the testing chamber.

### CROSS-REFERENCE TO RELATED APPLICATIONS

This application claims priority to U.S. Provisional Patent Application No. 60/592,668 (APPM/008500L), entitled “Electron Beam Test System Stage,” filed Jul. 30, 2004, and is incorporated by reference herein. This application is also a continuation in part of U.S. patent application Ser. No. 11/018,236 (APPM/008500.D01), entitled “Integrated Substrate Transfer Module,” filed Dec. 21, 2004, which is a divisional of U.S. patent application Ser. No. 10/778,982 (APPM/008500), now U.S. Pat. No. 6,833,717, which was filed Feb. 12, 2004 and issued Dec. 21, 2004, both applications are incorporated by reference herein.

### BACKGROUND OF THE INVENTION

1. Field of the Invention

Embodiments of the present invention generally relate to a test system for large area substrates. More particularly, the invention relates to an integrated electron beam testing system for large area substrates having one or more flat panel displays positioned thereon.

2. Description of the Related Art

Flat panel displays employ an active matrix of electronic devices, such as insulators, conductors, and thin film transistors (TFT's) to produce flat screens used in a variety of devices such as television monitors, personal digital assistants (PDA's), solar cells, and computer screens. Generally, these flat panel displays are made of two thin panels of glass, a polymeric material, or other suitable substrate material. Layers of a liquid crystal material or a matrix of metallic contacts, a semiconductor active layer, and a dielectric layer are deposited through sequential steps and sandwiched between the two thin panels which are coupled together to form a large area substrate having at least one flat panel display located thereon. At least one of the panels will include a conductive film that will be coupled to a power supply which will change the orientation of the crystal material and create a patterned display on the screen face.

One type of flat panel display includes a liquid crystal material sandwiched between two panels made of glass, a polymer material, or other suitable material capable of having electronic devices formed thereon. One of the panels may include a thin film transistor (TFT) array while the other panel may include a coating that functions as a color filter. The two panels are suitably joined to form a large area substrate having one or more flat panel displays located thereon.

A part of the manufacturing process requires testing of the large area substrate to determine the operability of pixels in the display or displays located on the large area substrate. Electron beam testing (EBT) is one procedure used to monitor and troubleshoot defects during the manufacturing process. In a typical EBT process, TFT response within a pixel electrode area is monitored to provide defect information by applying certain voltages to the TFT's while an electron beam is directed to an area of the large area substrate under investigation. Secondary electrons emitted from the area under investigation are monitored to determine the TFT voltages.

The demand for larger flat panel displays has created a need for new manufacturing systems that can accommodate larger substrate sizes. Current TFT LCD processing equipment is generally configured to accommodate substrates up to about 1.5×1.8 meters. However, processing equipment configured to accommodate substrate sizes up to and exceeding 1.9×2.2 meters is envisioned in the immediate future. Therefore, the size of the processing equipment, as well as the process throughput time, is a great concern to TFT LCD manufacturers, both from a financial standpoint and a design standpoint.

Therefore, there is a need for a compact testing system for large area substrates that conserves cleanroom space and that can reliably position the large area substrates in an EBT device.

### SUMMARY OF THE INVENTION

An integrated electron beam testing system is provided having a testing chamber capable of testing large area substrates utilizing electron beam columns. The testing chamber has a substrate support table adapted to move a substrate within the testing chamber in horizontal and vertical directions. The test system includes a load lock chamber adjacent a first side of the testing chamber and a prober transfer assembly adjacent a second side of the testing chamber. The prober transfer assembly is configured to transfer one or more probers between the testing chamber and a prober storage assembly adjacent the testing chamber. The testing chamber also includes a prober positioning assembly coupled to the substrate support table adapted to facilitate transfer of the one or more probers from the prober transfer assembly.

In one embodiment, a chamber for processing a substrate is described. The chamber includes a top, a bottom, at least one rigid sidewall coupled to the top and the bottom, and a movable sidewall. The top, the bottom, the rigid sidewall, and the movable sidewall define an interior region in fluid communication with a vacuum pump. The chamber also includes at least one actuator to move the movable side wall between an open position and a closed position, wherein the interior region is in communication with atmospheric conditions when the movable side wall is in a open position. In one embodiment, the movable sidewall is made of aluminum and is constructed to flex. In another embodiment, the at least one actuator moves the movable sidewall between the open position and the closed position in a vertical direction.

In another embodiment, a testing table for supporting and transferring a large area substrate is described. The testing table includes a segmented stage and an end effector integrated within the segmented stage, wherein the segmented stage is movable in a vertical direction and the end effector is movable in a first horizontal direction and wherein said stage and end effector are configured to support the large area substrate. In one embodiment, the segmented stage is a plurality of stage blocks having a slot between each stage block. Each slot is configured to receive a finger of the end effector.

In another embodiment, the one or more probers are transferred into and out of the testing chamber by a prober transfer apparatus having an outer frame coupled to a testing chamber, and an inner frame coupled to the outer frame. The inner frame includes a plurality of transfer arms sized to receive at least one prober frame. The inner frame is movable relative the outer frame facilitated by at least one vertical actuator. Each of the transfer arms is movable relative to the inner frame and is adapted to move into and out of the inner frame in a lateral movement. Each of the transfer arms has at least two support members configured to selectively engage at least two prober support members coupled to the prober frame. The at least two prober support members are adapted to selectively engage the prober positioning assembly. A prober transfer sequence is described where cooperative movement between the prober positioning assembly and the transfer arms facilitates prober transfer in and out of the testing chamber.

In another embodiment, the testing chamber includes a movable sidewall adjacent the prober transfer assembly. The movable sidewall is constructed of lightweight materials and is adapted to flex. In an open position, the testing chamber is open to ambient environment and prober transfer may occur. In a closed position, the movable sidewall is adapted to succumb to any negative pressure provided to the testing chamber to form a seal from ambient environment.

A method of transferring one or more probers into and out of an electron beam testing chamber is also provided. In one embodiment, the method includes moving at least one prober from a prober storage assembly to at least one transfer arm on a prober transfer assembly, opening a prober transfer door coupled to the testing chamber, extending the at least one transfer arm into the testing chamber, disengaging the at least one prober from the transfer arm, engaging the at least one prober to a positioning device coupled to a substrate support table, retracting the at least one transfer arm out of the testing chamber; and closing the prober transfer door.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic perspective view of an exemplary electron beam test system having one embodiment of a prober transfer assembly.

FIG. 2 is another embodiment of an exemplary electron beam test system having another embodiment of a prober transfer assembly.

FIG. 3 shows an enlarged schematic cut-away view of one embodiment of a load lock chamber.

FIG. 4 shows a partial cross-sectional view of a load lock chamber and a testing chamber.

FIG. 5 shows an enlarged cross-sectional view of the testing chamber shown in FIG. 4.

FIGS. 6 and 7 show isometric views of exemplary drive systems for the substrate support table.

FIG. 8A shows an isometric plan view of an illustrative end effector and a substrate support table.

FIG. 8B shows an isometric cross-sectional view of the end effector within the substrate support table.

FIG. 9A shows an isometric view of one embodiment of a multi-panel stage.

FIG. 9B is an exploded isometric view of a linking bar for connecting adjacently positioned stage blocks.

FIG. 9C shows a perspective view of a lower surface of the multi-panel stage depicted in FIG. 9A.

FIG. 9D is a perspective bottom view of one embodiment of a multi-panel stage.

FIG. 9E shows a cross-sectional view of the multi-panel stage along section line E-E of FIG. 9D.

FIG. 9F shows a cross-sectional view of the multi-panel stage along section line F-F of FIG. 9D.

FIG. 9G shows a cross-sectional view of the multi-panel stage along section line G-G of FIG. 9D.

FIG. 9H shows a cross-sectional view of the multi-panel stage along section line H-H of FIG. 9D.

FIG. 9I is a partial cross-sectional view of a Z-actuator in a nominal down position.

FIG. 9J is a partial cross-sectional view of a Z-actuator in an extended up position.

FIG. 10 shows a basic schematic plan view of a substrate support table, an end effector, a prober, a Z-stage, and EBT columns.

FIG. 11A is an isometric view of one embodiment of a prober.

FIG. 11B is a partial sectional view of the lower surface of a prober.

FIG. 11C is a perspective view of a prober above a substrate support table.

FIG. 12 is an isometric view of another embodiment of a prober.

FIG. 13 shows a schematic isometric view of one embodiment of a prober transfer assembly.

FIG. 14A shows an isometric view of a prober positioning assembly.

FIG. 14B is a schematic view of a prober positioning assembly within the chamber body above the substrate support table.

FIG. 14C is a schematic plan view of the prober frame in a position for transfer to the prober positioning assembly.

FIG. 14D is a schematic plan view of the prober frame supported by the prober positioning assembly.

FIG. 14E is a schematic plan view showing the prober frame supported by a spacer coupled to a substrate support table.

FIG. 14F shows the prober frame and the prober supported by the spacer and the prober positioning assembly in a position that does not interfere with any movement of the substrate support table.

FIG. 15A shows an isometric view of one embodiment of a prober exchanger.

FIG. 15B is a partial isometric view showing one end of a transfer member support.

FIG. 15C is a partial isometric bottom view of an exemplary exchanger transfer interface.

FIG. 16 is an isometric view of another embodiment of a test system.

FIGS. 17-30 are cross-sectional views of one embodiment of the load lock chamber and the testing chamber illustrating one embodiment of an operational sequence.

### DETAILED DESCRIPTION OF THE PREFERRED EMBODIMENT

An integrated test system requiring minimum space capable of testing large area substrates made of glass, a polymer material, or other suitable material, up to and exceeding 1.9 meters by 2.2 meters is provided. As will be described below, the test system provides stable substrate handling, reduces substrate alignment time, reduces unwanted particle generation, and provides improved test accuracy, reliability and repeatability. For purposes of this disclosure, the term test system means any system that may be used to test electronic devices on a substrate. Such a test system may include optical inspection systems, electron beam test systems, and systems that detect color changes, among others. For simplicity and ease of description, an electron beam test system will be further described.

The term substrate as used herein refers generally to large area substrates made of glass, a polymeric material, or other substrate materials suitable for having an electronic device formed thereon. Embodiments depicted in this application will refer to various drives, motors and actuators that may be one or a combination of the following: a pneumatic cylinder, a hydraulic cylinder, a magnetic drive, a stepper or servo motor, a screw type actuator, or other type of motion device that provides vertical movement, horizontal movement, combinations thereof, or other device suitable for providing at least a portion of the described motion.

Various components described herein may be capable of independent movement in horizontal and vertical planes. Vertical is defined as movement orthogonal to a horizontal plane and will be referred to as Z direction. Horizontal is defined as movement orthogonal to a vertical plane and will be referred to as X or Y direction, the X direction being movement orthogonal to the Y direction, and vice-versa. The X, Y, and Z directions will be further defined with directional insets included as needed in the Figures to aid the reader.

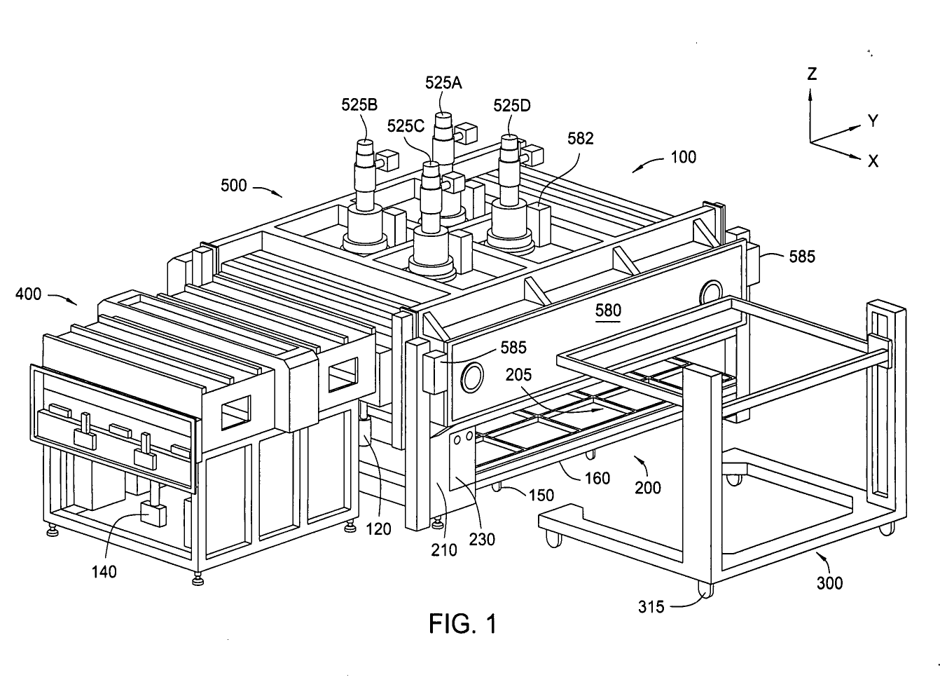

FIG. 1 shows a schematic view of an exemplary electron beam test (EBT) system 100. The illustrated EBT system 100 is capable of testing large area substrates, up to and exceeding 1.9 meters by 2.2 meters. The EBT system 100 includes a prober storage assembly 200, a prober transfer assembly 300, a load lock chamber 400, and a testing chamber 500. The testing chamber defines an enclosure that includes a top, a bottom, at least one sidewall rigidly coupled to the top and the bottom, and a movable sidewall 580 opposing the rigidly coupled sidewall. A plurality of electron beam columns are shown disposed on an upper surface of the testing chamber 500. In the embodiment depicted in FIG. 1, four electron beam columns 525A, 525B, 525C, 525D and at least one microscope assembly 582 are shown coupled to an upper surface of the testing chamber 500. The microscope assembly 582 is adapted to review areas of interest on the substrate. The load lock chamber 400 is disposed adjacent and connected to the testing chamber 500. Typically, the load lock chamber 400 and the testing chamber 500 are selectively isolated by a slit valve and both chambers are capable of maintaining independent environments by means of vacuum pumps 120 and 140. However, these chambers 400, 500 may share a common environment which may be maintained at vacuum conditions by the pump 120 coupled through the testing chamber 500 or the pump 140 coupled to the load lock chamber 400. Typically, the testing chamber 500 is selectively maintained under vacuum. The load lock chamber 400 transfers substrates between the testing chamber 500 and ambient environment outside the load lock chamber 400, which is typically a cleanroom at atmospheric pressure. The load lock chamber 400 may function as an isolated processing environment that is capable of being heated or cooled, depending on system requirements. Consequently, load lock chamber 400 enables the transfer of substrates into and out of the testing chamber 500 without exposure to outside contaminants.

The EBT system 100 also includes a movable sidewall 580 that is adapted to facilitate transfer of one or more probers 205 into and out of the testing chamber 500. In one embodiment, the movable sidewall 580 is an elongate member that spans a length of the testing chamber 500 and includes an open position and a closed position. In the open position, the movable sidewall is adapted as a prober transfer door that allows ample room for prober transfer while providing access to the interior of the testing chamber 500. In this embodiment, the movable sidewall 580 is configured to provide enhanced sealing in the closed position as the perimeter of the movable sidewall 580 contacts areas of the testing chamber that provide a stronger sealing face. In one embodiment, the movable sidewall 580 forms at least a portion of the sidewall of the chamber. The perimeter of the movable sidewall contacts areas adjacent an upper and a lower portion of, and areas adjacent the corners of the testing chamber 500. This contact at the upper, lower, and corners of the testing chamber 500 provides a seal that is superior to other ports that are formed in or through a wall of the testing chamber. The movable sidewall 580 is coupled to an actuator system 585 on the testing chamber 500 that opens and closes the movable sidewall 580 when desired. In one embodiment, the movable sidewall 580 functions as a wall of the chamber when closed and sealed, and opens at least in a vertical direction along a side of the testing chamber 500. The movable sidewall 580 is adapted to assist prober transfer in an open position and provides a vacuum tight seal to the testing chamber 500 in a closed position. In one embodiment, the movable wall 580 is of a material and design that renders the movable wall substantially flexible. In a closed position, the movable wall 580 is adapted to partially succumb to any negative pressure applied to the interior of the testing chamber 500, thereby flexing to aid in a vacuum tight seal on one portion of the testing chamber 500. The movable sidewall 580 may be fabricated from lightweight materials, such as aluminum, and may include an O ring adapted to aid in sealing when closed. In this manner the movable sidewall 580 may succumb to the lower pressure from the vacuum pump 120 to provide sufficient sealing from ambient environment by this flexibility. The movable sidewall 580 may also be opened to provide access to the interior of the testing chamber 500 for servicing and inspection, which may decrease downtime as personnel may not need to disassemble the testing chamber 500. This also conserves cleanroom space as the movable sidewall is adjacent a side of the testing chamber when open.

The prober storage assembly 200 provides storage for one or more probers 205 proximal the testing chamber 500 for easy use and retrieval. The prober storage assembly 200 is disposed beneath the testing chamber 500 to conserve cleanroom space. The prober storage assembly 200 has dimensions approximating those of the testing chamber 500 and is disposed on a mainframe 210 supporting the testing chamber 500. The prober storage assembly 200 may include a skid assembly 160 that may be moved around the mainframe 210 and to provide support for the one or more probers 205. The skid assembly 160 may have wheels, such as rollers 150, to allow the skid assembly 160 to move in and out of the prober storage assembly 200. Alternatively, the skid assembly 160 may be fixed to the mainframe 210 and the probers 205 may be retrieved from and returned to the prober storage assembly 200 by a prober transfer assembly 300. In one embodiment, the prober transfer assembly may be equipped with wheels such as casters 315. The prober storage assembly 200 may further include a retractable door 230 that can seal off the storage area and protect the stored probers 205 when not in use.

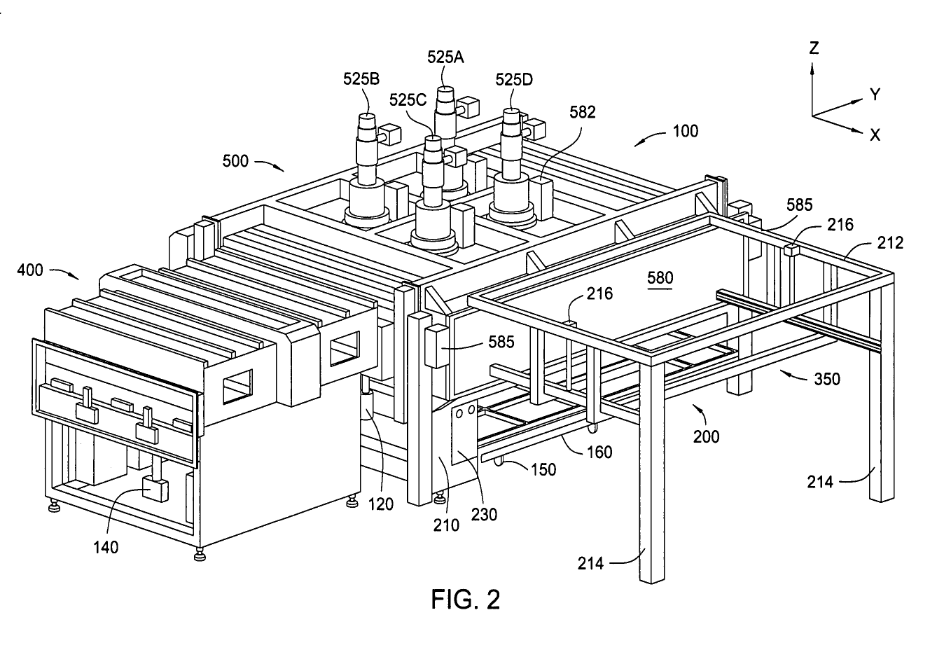

FIG. 2 depicts another embodiment of an exemplary EBT system 100 similar to the embodiment shown in FIG. 1, with the exception of a prober exchanger 350 provided as an alternative to the prober transfer assembly 300. The prober exchanger 350 is a modular unit disposed adjacent the testing chamber 500 and is adapted to provide temporary storage and facilitate transfer for one or more probers 205 between the prober storage assembly 200 and the testing chamber 500.

The prober exchanger 350 is positioned adjacent the movable sidewall 580 and includes an outer frame 212, at least one inner frame 213, and at least one vertical actuator 216 coupled therebetween. The at least one inner frame 213 is configured to support and facilitate transfer of at least one prober 205. The prober exchanger 350 in this embodiment is supported on one side by the testing chamber 500 and on the other side by two outer supports 214.

Load Lock Chamber

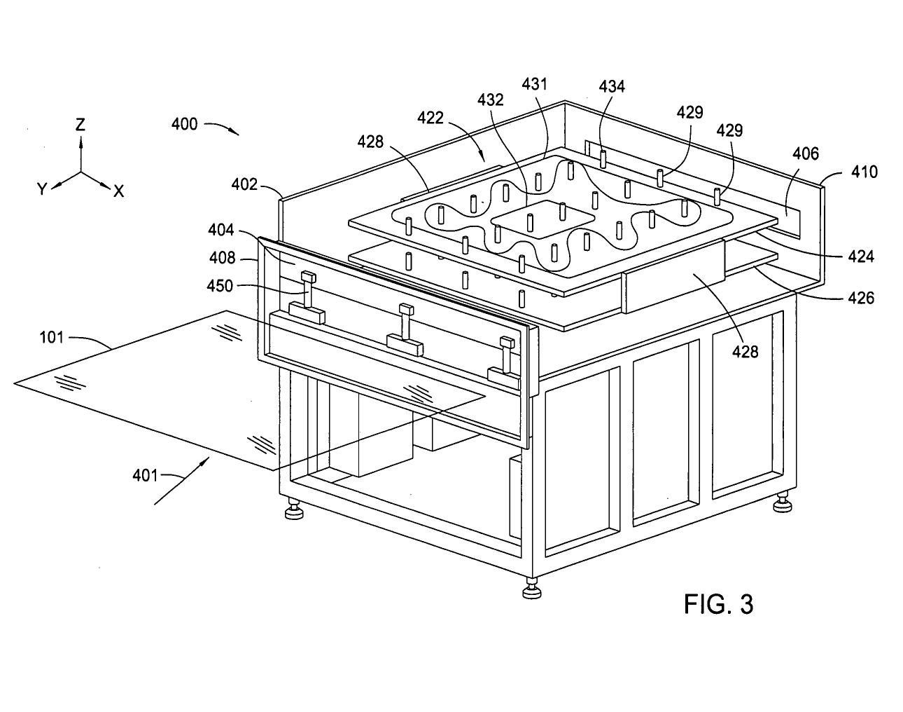

FIG. 3 shows a cut-away schematic view of one embodiment of a load lock chamber 400 having a dual slot substrate support. The load lock chamber 400 includes a chamber body 402 and a dual slot substrate support 422 disposed therein. The chamber body 402 includes at least a first sealable port 404 and a second sealable port 406, which may be sealed by a door of a slit valve coupled to sidewalls 408, 410 respectively, to isolate an interior environment of the chamber body 402. The first port 404 typically couples the load lock chamber 400 to a factory interface, such as a facility loading device, a substrate queuing system, a processing system, a conveyor, or other device. The slit valve 406 is typically disposed between the load lock chamber 400 and the testing chamber 500 to facilitate substrate transfer therebetween.

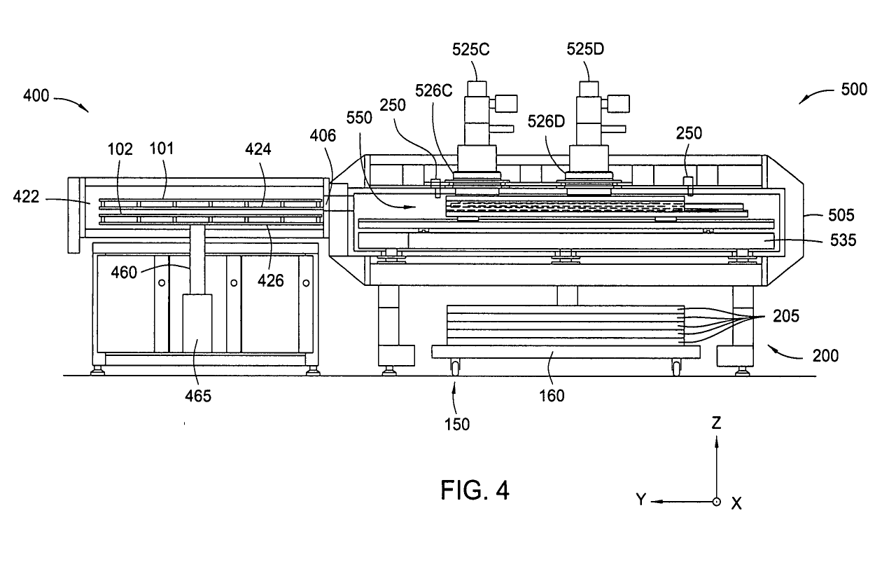

Referring additionally to FIG. 4, the dual slot support 422 is disposed on a shaft 460 connected to a lift actuator 465. The lift actuator 465 allows the dual slot support 422 to move in a Z direction within the chamber body 402 to facilitate substrate transfer to and from ambient environment and to and from the testing chamber 500 through the ports 404, 406. The dual slot support 422 includes a first substrate support tray 424 and a second substrate support tray 426 that are maintained in a stacked, spaced-apart relationship by a pair of vertical supports 428.

The load lock chamber 400 may include one or more heating elements 431 and/or one or more cooling elements 432 attached to the substrate support trays 424, 426 to control the temperature of the substrates positioned within the load lock chamber 400. Further, a heat exchanger (not shown) may be disposed within the sidewalls of the chamber body 402. Alternatively or additionally, a non-reactive gas, such as nitrogen and/or helium, may be passed through the load lock chamber 400 to transfer heat in and out of the chamber 400.

Each tray 424, 426 is configured to support a substrate 101 thereon. Typically, one or more support pins 429 are coupled to, or at least partially disposed through an upper surface of each substrate support tray 424, 426, to support the substrate. The support pins 429 may be of any height, and provide a pre-determined spacing between a lower surface of a substrate and the upper surface of the substrate support tray 424 or 426. The spacing prevents direct contact between the substrate support trays 424, 426 and the substrates, which may cause damage to the substrates or result in contaminants being transferred from the substrate support trays 424, 426 to the substrates.

In one embodiment, the support pins 429 have rounded upper portions 434 that contact a substrate supported thereon. The rounded upper portions 434 reduce surface area in contact with the substrate, thereby reducing the probability of scratching the substrate. In one embodiment, the upper portion 434 may have a hemispherical, ellipsoidal, or parabolic shape. The upper portion 434 may have either a machined or polished finish or other suitable finish of adequate smoothness. In another embodiment, the upper portion 434 has a surface roughness no greater than 4 micro inches. In another embodiment, the rounded upper portion 434 of the support pin 429 is coated with a chemically inert material to reduce or eliminate chemical reactions between the support pins 429 and the substrate supported thereon. Additionally, the coating material may minimize friction with the substrate to reduce breakage or chipping. Suitable coatings include nitride materials, such as silicon nitride, titanium nitride, and tantalum nitride, for example. A more detailed description of such support pins and coatings may be found in U.S. Pat. No. 6,528,767, which issued Mar. 4, 2003, entitled “Pre-heating and Load Lock Pedestal Material for High Temperature CVD Liquid Crystal and Flat Panel Display Applications,” which is incorporated by reference herein.

In another embodiment, the support pins 429 may be a two piece system. The two piece system can include a mounting pin disposed on an upper surface of the support tray 422, 426, and a cap disposable on the mounting pin. The mounting pin is preferably made of a ceramic material. The cap has a hollow body to receive the mounting pin. The upper portion of the cap can be rounded and smoothed as discussed above. Similarly, the cap can be coated as described above. A more detailed description of such a two piece system may also be found in U.S. Pat. No. 6,528,767, which issued Mar. 4, 2003, entitled “Pre-heating and Load Lock Pedestal Material for High Temperature CVD Liquid Crystal and Flat Panel Display Applications,” previously incorporated by reference above.

In yet another embodiment, an upper portion 434 of the support pins 429 can include a socket that retains a ball moveable within the socket. The ball makes contact with and supports the substrate disposed thereon. The ball is allowed to rotate and spin, much like a ball bearing, within the socket, allowing the substrate to move across the ball without scratching. The ball is generally constructed of either metallic or non-metallic materials that provide friction reduction and/or inhibit chemical reaction between the ball and the substrate. For example, the ball may include a metal or metal alloy, quartz, sapphire, silicon nitride or other suitable non-metallic materials. Preferably, the ball has a surface finish of 4 micro-inches or smoother. The ball may further include the coating describe above. A more detailed description of such a support pin may be found in U.S. Pat. No. 6,528,767, which issued Mar. 4, 2003, entitled “Pre-heating and Load Lock Pedestal Material for High Temperature CVD Liquid Crystal and Flat Panel Display Applications,” previously incorporated by reference above.

Alternatively, the support pins 429 can include a mounting pin disposed on an upper surface of the support tray 424 or 426, and a cap disposable on the mounting pin, whereby the cap includes the socket and ball configuration described above. A more detailed description of such a ball and socket may be found in co-pending U.S. Patent Publication No's. 2003/0072639, filed Oct. 17, 2001, and 2004/0170407, filed Feb. 27, 2003, both entitled “Substrate Support,” and both assigned to Applied Materials, Inc. Both co-pending applications are incorporated by reference herein.

Further, the support pins 429 may include a housing having one or more roller assemblies and a support shaft at least partially disposed therein. The support shaft is able to move axially through the housing as well as rotate within the housing to reduce wear and tear on the pin head during loading and unloading of a substrate supported thereon. The support pins 429 may also include a housing having one or more ball assemblies and a support shaft at least partially disposed therein. The ball assemblies include one or more spherical members that are held into place by a sleeve that is at least partially disposed about the housing. The one or more spherical members contact the shaft and allow the shaft to move axially as well as radially within the housing. This also reduces wear and tear on the pin head during loading and unloading of a substrate supported thereon. A more detailed description of such support pins may be found in commonly assigned and co-pending U.S. patent application Ser. No. 10/779,130, filed Feb. 12, 2004, entitled “Substrate Support Bushing,” which is incorporated by reference herein.

In an exemplary operation, a substrate 101, such as a large area substrate having a plurality of 17 inch displays formed thereon is introduced into the load lock chamber 400 by a facility loading device through the first sealable port 404 in the direction of arrow 401 and placed on one of the support trays 424, 426, for example on support tray 424. In this example, support tray 426 may be unused in order to receive a substrate B that has completed the testing sequence and is to be transferred out of the testing chamber 500 to the load lock chamber 400. Alternatively, the support tray 426 may be supporting a previously tested substrate that is in condition to be transferred out of the load lock chamber 400 to ambient environment prior to the introduction of the substrate 101 into the load lock chamber 400. Regardless of placement of the substrate 101 on a particular support tray, once the substrate 101 is supported by the support pins 429 and the facility loading device has exited the interior of environment of the chamber body 402, the first sealable port 404 may be closed and the load lock chamber pumped down to a predetermined vacuum level. When or while the load lock chamber 400 is pumped down to the predetermined pressure, the substrate 101 may be heated or cooled. The substrate 101 is then transferred through the port 406 to the testing chamber 500 for testing.

FIG. 4 shows a partial cross-sectional view of the load lock chamber 400 and the testing chamber 500. The testing chamber 500 includes a housing 505, one or more electron beam testing (EBT) columns (columns 525C and 525D are shown), a base 535, and a substrate support table 550. The EBT columns 525C, 525D are disposed on an upper surface of the housing 505 and are coupled to the housing 505 via openings 526C, 526D formed through the upper surface thereof. The housing 505 provides a particle free environment and encloses the substrate support table 550 and the base 535. The base 535 is fixed at the bottom of the housing 505 and supports the substrate support table 550. An upper portion of the substrate support table supports a testing device, such as a prober (not shown). Substrate 101 and substrate 102 are shown supported by support tray 424 and support tray 426 respectively, in the load lock chamber 400. A prober positioning assembly 250 is coupled to an upper surface of the testing chamber 500 to facilitate prober transfer into and out of the testing chamber.

In an exemplary operation, substrate 101 is in a transfer position for entering the testing chamber 500. The slit valve 406 of the load lock chamber 400 may be opened to allow substrate 101 to be transferred into the testing chamber 500 by cooperative movement of an end effector and the substrate support table 550, which will be explained in detail below.

Substrate Support Table

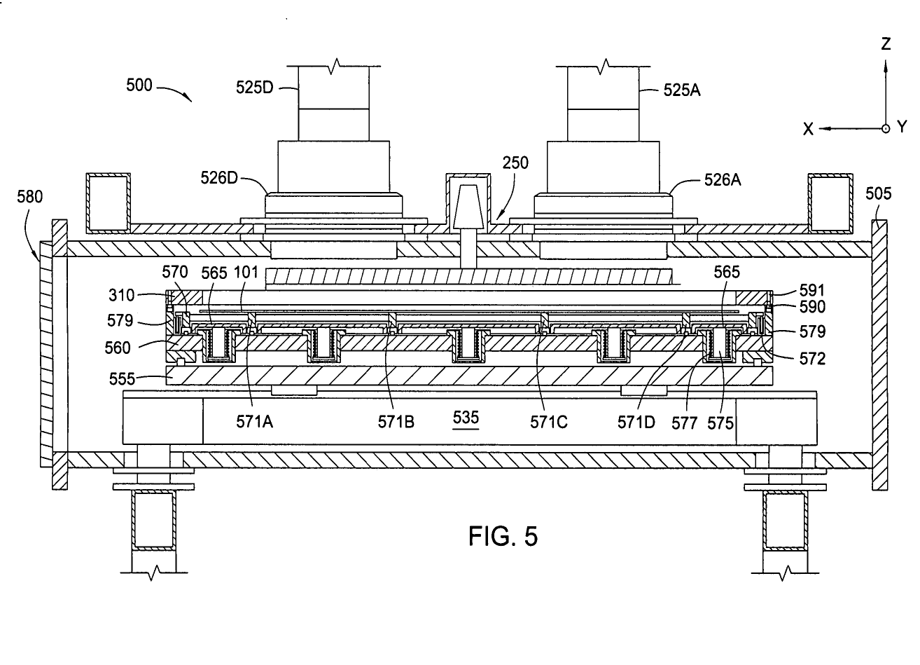

FIG. 5 shows an enlarged cross-section view of the testing chamber 500 shown in FIG. 4. The substrate support table 550 includes a first stage 555, a second stage 560, and third stage 565. The three stages 555, 560, and 565 are substantially planar plates, and are stacked on one another. In one aspect, each of the three stages 555, 560, 565 independently move along orthogonal axes or dimensions. For simplicity and ease of description, the first stage 555 will be further described below as representing the stage that moves in the X direction and will be referred to as the lower stage 555. The second stage 560 will be further described below as representing the stage that moves in the Y direction and will be referred to as the upper stage 560. The third stage 565 will be further described below as representing the stage that moves in the Z direction and will be referred to as the Z-stage 565.

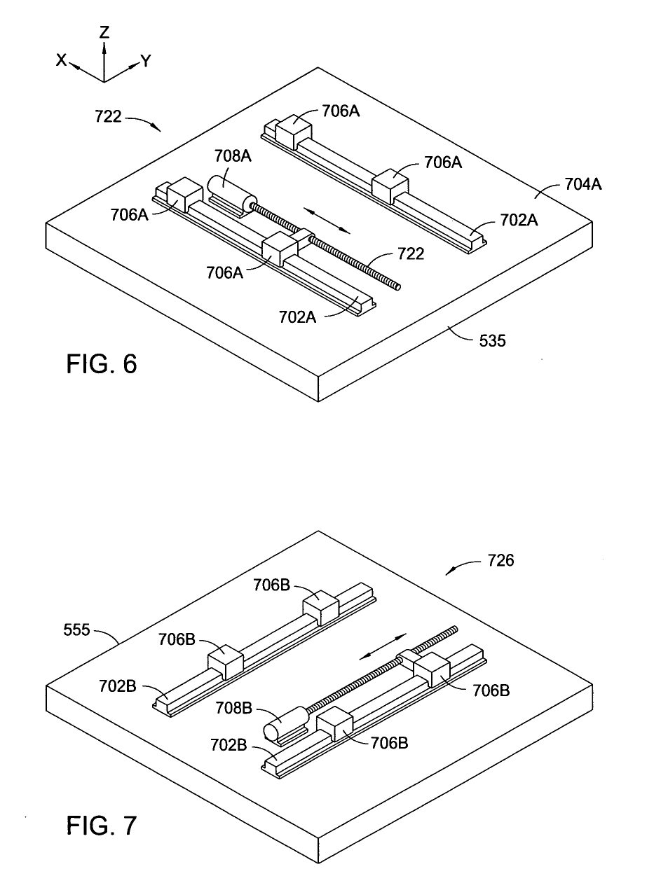

The lower stage 555 is coupled to a base 535 through a first drive system (shown in FIGS. 6, 7). The first drive system moves the lower stage 555 linearly in the X direction. Similarly, the upper stage 560 is coupled to the lower stage 555 through a second drive system, (shown in FIGS. 6, 7) which moves the upper stage 560 linearly in the Y direction. The first drive system is capable of moving the substrate support table 550 in the X direction by at least 50 percent of a length or width of the substrate. Likewise, the second drive system is capable of moving the substrate support table 550 in the Y direction by at least 50 percent of a length or width of the substrate.

FIGS. 6 and 7 show schematic isometric views of one embodiment of these drive systems utilized to move the lower stage 555 and the upper stage 560. Referring to FIG. 6, the first drive system 722 generally includes a pair of linear rails 702A coupled to the base 535. A plurality of guides 706A are movably engaged with the rails 702A and are coupled to an upper surface 704A of the lower stage 555 (not shown in this view). The guides 706A move along the rails 702A, thereby allowing the lower stage 555 to move over the base 535 in an X direction. Linear motor 708A, is coupled between the lower stage 555 and the base 535 to control the position of the guides 706A. The lower stage 555 is coupled to each of the guides 706A, allowing the lower stage 555 to move in response to the actuator 708A.

Referring to FIG. 7, the upper stage 560 is coupled to the lower stage 555 via the second drive system 726. The second drive system 726 is configured similar to the first drive system 722 except the second drive system 726 is oriented in a direction orthogonal to the first drive system 722. Similar to the lower stage 555 above, a lower surface of the upper stage 560 is coupled to each of the guides 706B, allowing the upper stage 560 to move in response to the linear motor 708B. Generally, the drive systems 722, 726 have a range of motion that allows all of the surface area of a substrate disposed within the testing chamber 500 to be moved beneath the EBT columns 525 during testing. The drive systems 722, 726 also provide motion to the substrate support table 550 that facilitates prober and substrate transfer into and out of the testing chamber 500.

End Effector/Multi-Panel Stage

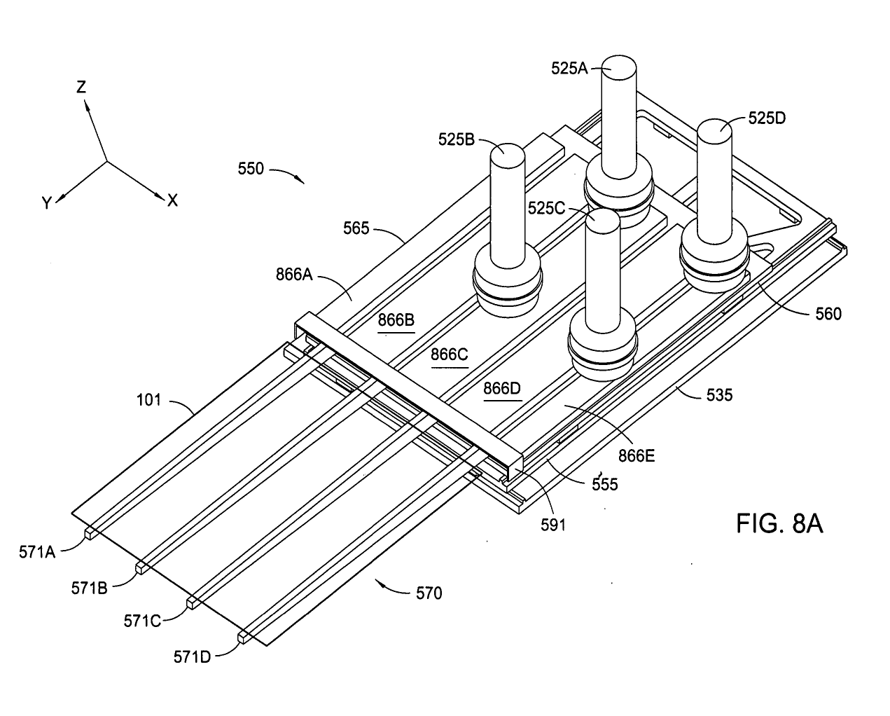

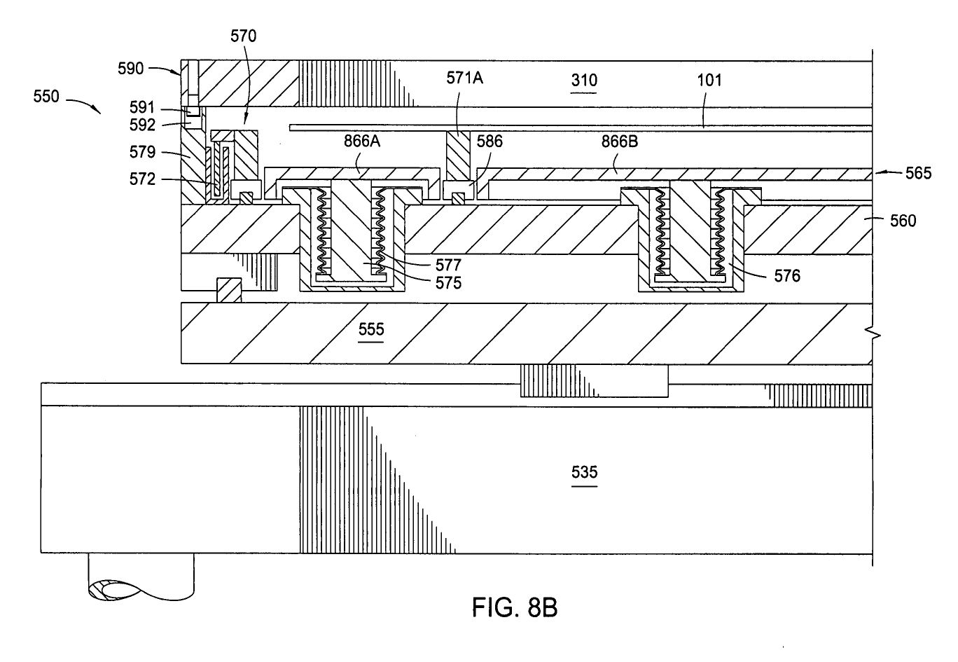

FIG. 8A shows a schematic plan view of one embodiment of an end effector 570. In one embodiment, the end effector 570 includes a plurality of fingers that rests on an upper surface of the upper stage 560 having a planar or substantially planar upper surface on which the substrate 101 may be supported. The end effector 570 may have two or more fingers connected at least on one end by a support connection 591. The support connection 591 is adapted to couple each of the fingers to allow all of the fingers to move simultaneously. Each finger of the end effector 570 may be separated by a slot or space within the Z stage 565. The actual number of fingers is a matter of design and is well within the skill of one in the art to determine the appropriate number of fingers needed for the size of substrate to be manipulated. For example, the end effector 570 can have four fingers 571A, 571B, 571C, and 571D that are evenly spaced, which contact and support the substrate 101 when placed thereon. The substrate 101 is disposed on and supported by the fingers 571A-571D which form a substantially planar surface for the substrate. The fingers 571A-571D move in and out of the Z-stage 565 such that the fingers 571A-571D interdigitate with the segments 866A, 866B, 866C, 866D, and 866E when the end effector 570 is disposed in substantially the same plane as the Z-stage 565. This configuration allows the end effector 570 to freely extend and retract from the substrate support table 550 to the load lock chamber 400. As will be described below, the Z-stage 565 is capable of elevating above the end effector 570 to place the substrate 101 in contact with the Z-stage 565.

FIG. 8B shows a more detailed cross-section of the view shown in FIG. 5 showing the placement of the end effector 570 within the substrate support table 550. The Z-stage 565 has a planar or substantially planar upper surface to contact and support the substrate 101 within the testing chamber 500 and is disposed on an upper surface of the upper stage 560. The Z-stage 565 is slotted or segmented such that each segment of the Z-stage 565 sits adjacent the fingers 571A-571D of the end effector 570. As the fingers are connected by the support connection 591, the end effector 570 may have two guide members 572 (only one is shown in this view) to facilitate horizontal movement of the end effector 570. The guide members 572 may be part of a drive system as discussed above and is configured to provide at least horizontal movement to the end effector 570. As such the Z-stage 565 and the end effector 570 can be operated on the same horizontal plane which allows the Z-stage 565 to move above and below the end effector 570. Accordingly, the spacing between the segments of the Z-stage 565 corresponds to the width of the fingers of the end effector 570 plus some additional measure to assure clearance. Although five segments are shown in the cross-section view of FIG. 5, the Z-stage 565 may have any number of segments.

In operation, the end effector 570 can be extended from the testing chamber 500 into the load lock chamber 400 in a Y direction. The fingers 571A-571 D are sized and spaced to reconcile the configuration of the support pins 429 on the support trays 424, 426 and the fingers may enter the load lock chamber 400 below the substrate to be extracted and retract back into the testing chamber 500 through the slit valve 406. Likewise, the end effector 570 having a substrate loaded thereon may be extended from the testing chamber 500 through the slit valve 406 into the load lock chamber 400 to transfer the substrate to the load lock chamber 400. Horizontal actuators (not shown) and linear bearings 586 may be used to assist in this extension and retraction into and out of the testing chamber 500.

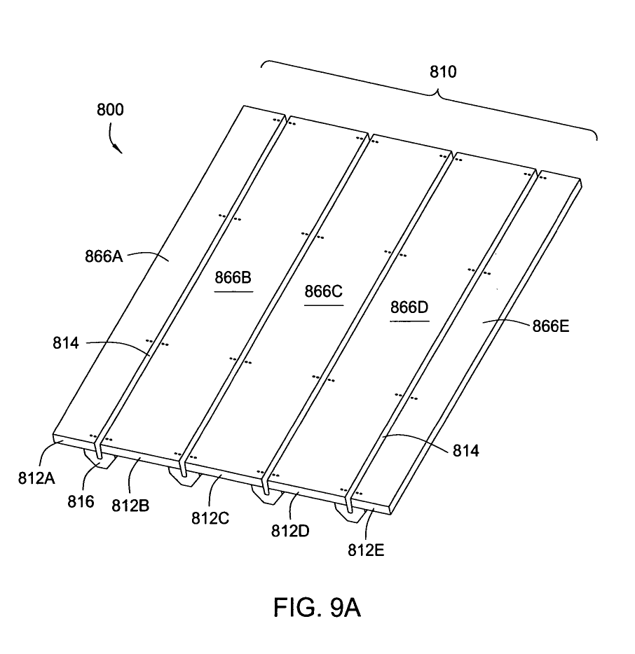

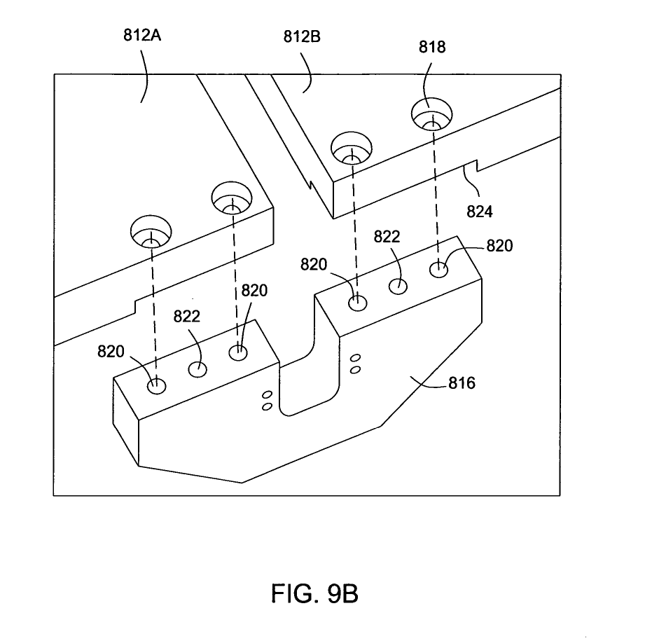

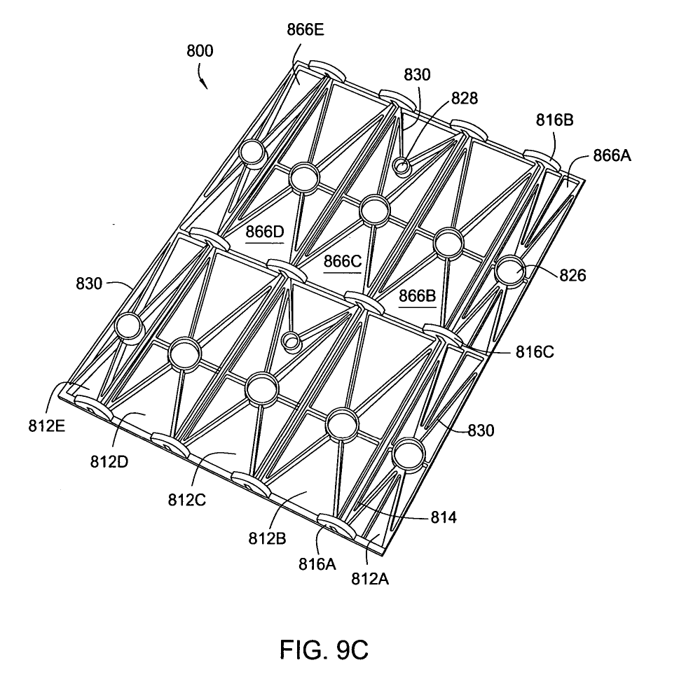

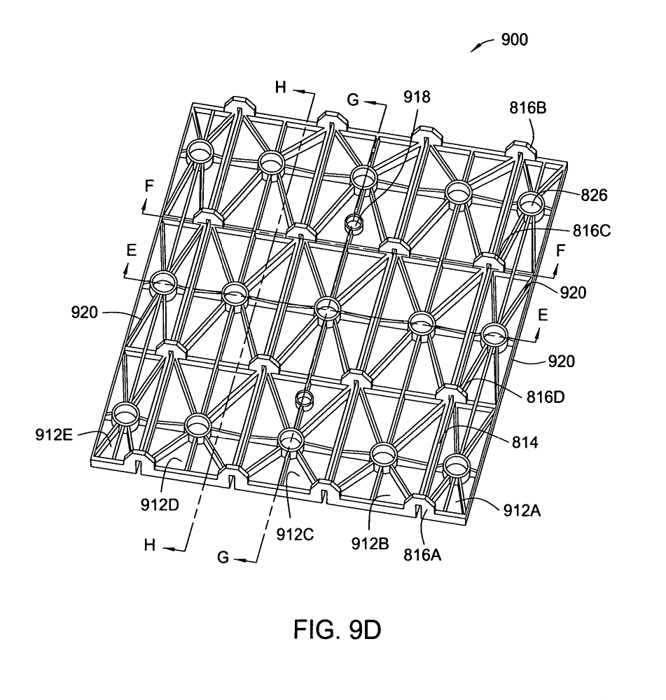

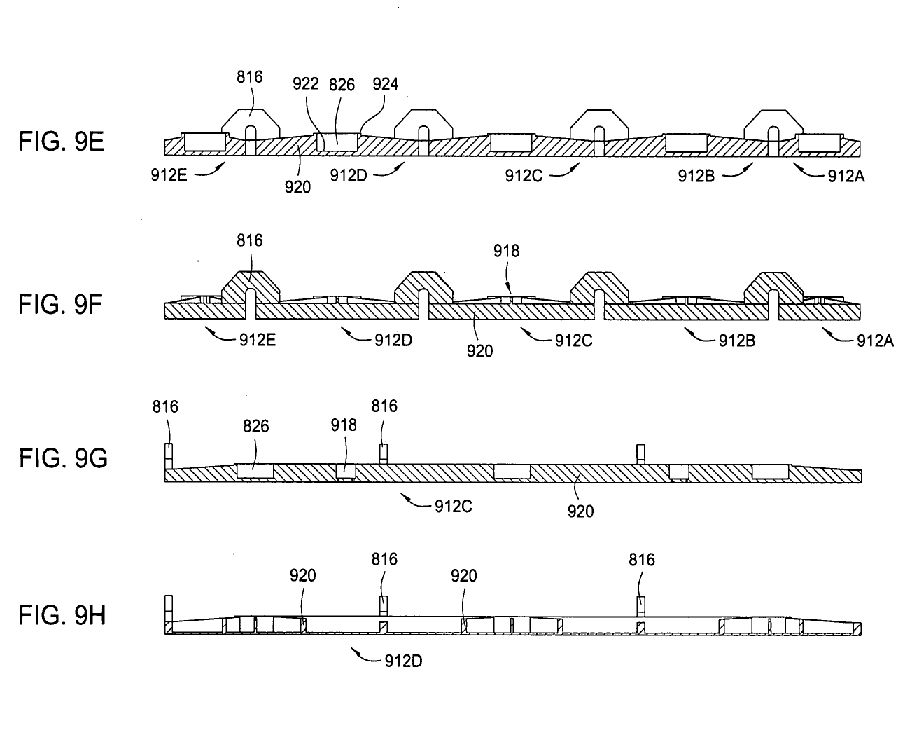

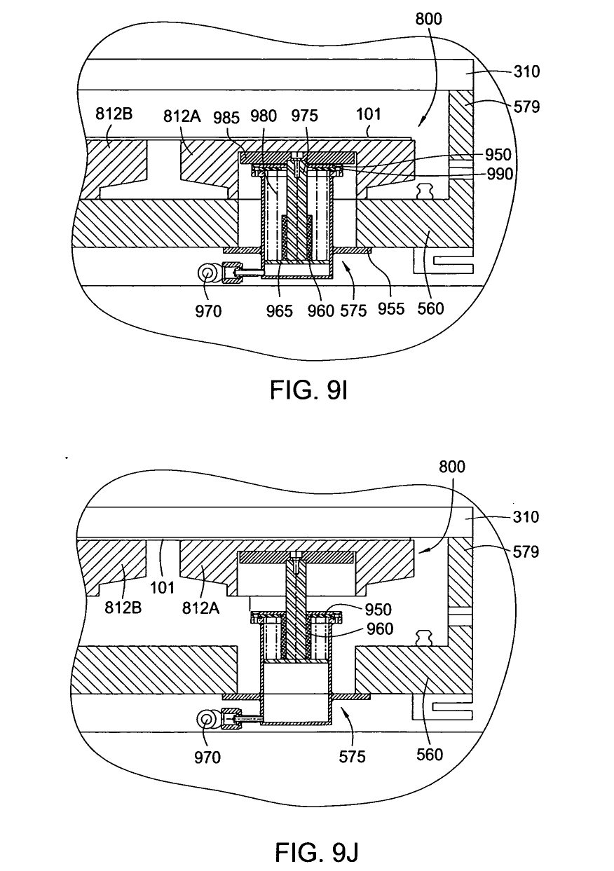

FIG. 9A shows one embodiment of a Z stage 565 as a segmented platform or a multi-panel stage 800. The multi-panel stage 800 has a testing surface 810 comprising the top surfaces of five stage blocks 812A, 812B, 812C, 812D, 812E positioned in a spaced-apart relationship within a single plane. Each area between adjacent stage blocks 812A-812E define a slot 814 and are connected together using linking bars 816. Preferably, the adjacently positioned stage blocks are spaced apart with sufficient distance to define a slot 814 having sufficient width to accommodate the width of a finger 571A-571D of the end effector 570. Although the linking bars 816 may have essentially any shape, the preferable shape of the linking bars 816 is generally a “U”-shape so as to provide sufficient clearance to accommodate the height of a finger 571A-571D of the end effector 570.

For enhancing flatness of the multi-panel stage 800, each of the stage blocks 812A-812E may be fabricated from a single monolithic piece of material. Alternatively, the each of the stage blocks 812A-812E may be fabricated separately and then machined to a preferred flatness. Suitable materials for the multi-panel stage 800 include rigid materials such as metals and ceramics. Metal materials include aluminum alloys due to their light weight and high stiffness properties.

The multi-panel stage 800 can have any combination of dimensions that exceed the dimensions of a substrate. In one embodiment, the multi-panel stage 800 may have a testing surface 810 sized to accommodate a large area substrate having a surface area of at least about 40,000 cm². In another embodiment, the multi-panel stage 800 may have a testing surface 810 sized to accommodate a large area substrate having a surface area of about 50,000 cm². In yet another embodiment, the multi-panel stage 800 may have a testing surface 810 sized to accommodate a large area substrate having a surface area of about 60,000 cm² or larger. The substrate support table 550 and other components of the test system 100 will be scaled to accommodate any of the above sizes of the multi-panel stage 800.

FIG. 9B is an enlarged perspective view of a linking bar 816 for connecting adjacently positioned stage blocks. Linking bar 816 is attached to a bottom surface of adjacently positioned stage blocks 812A and 812B using screws threaded through a pair of counter-sunk holes 818, provided in each of the upper surfaces of the adjacently positioned stage blocks 812A and 812B, and corresponding holes 820 in the linking bar 816. To minimize shear forces that may be encountered by the screws and to enhance alignment, a dowel (not shown) provided on a bottom surface of each of the adjacently positioned stage blocks 812A and 812B is inserted into corresponding hole 822 in the linking bar 816. Additionally, a recess 824 may be machined in the bottom surfaces of the adjacently positioned stage blocks 812A and 812B for receiving the linking bar 816 and providing additional rigidity.

FIG. 9C shows an isometric view of a lower surface of the multi-panel stage 800 depicted in FIG. 9A. The multi-panel stage 800 includes at least two linking bars 816A and 816B located at each end of the adjacently positioned stage blocks 812A and 812B, and a third linking bar 816C positioned between the ends. Depending upon the length of the multi-panel stage, any number of linking bars 816 may be used between adjacently positioned stage blocks to maintain flatness, and provide additional support and rigidity to the multi-panel stage 800.

The multi-panel stage 800 may be configured to receive one or more Z stage actuators 575 (FIG. 8B) adapted to move the Z stage 565 in a Z direction. Preferably a plurality of Z stage actuators 575 are attached to a lower surface of the multi-panel stage 800 at different locations in order to minimize deflection of the stage weight under the force of gravity and to ensure that any resulting deformation of the stage is maintained within the requisite flatness specifications. FIG. 9C shows ten actuator receptacles 826, each configured to receive an upper end of a Z stage actuator 575. The Z-actuator receptacle 826 generally comprises a circular-shaped ridge configured to reduce lateral movement of a Z stage actuator mounted therein. In addition, to assist in minimizing lateral movement of the multi-panel stage 800, linear bearing receptacles 828 may be provided, which comprise a circular-shaped ridge configured to receive an upper end of a Z bearing (not shown) and reduce lateral movement thereof. Although many different types of linear bearings may be used, one example of a linear bearing is a standard stainless steel linear bearing, such as a SWF-W Type linear bearing and may also be suitable for use in a vacuum environment.

Ridges 830 that extend outwardly from each individual Z actuator receptacle 826, each linear bearing receptacle 828, and along the edges of each of the stage blocks 812A-812E enhance strength and rigidity of the stage while minimizing the stage weight. The ridges 830 that extend from the Z actuator receptacles 826 and the linear bearing receptacle 828 are generally thicker near the receptacles 826, 828 and may taper in thickness along the length of the ridge. The geometry and locations of the receptacles 826, 828 as well as the geometry and dimensions (e.g., width, thickness) of the ridges 830 may be optimized for a particular multi-panel stage 800 having desired stage parameters such as stage length, width, requisite flatness, stage material, and stage weight. One method of optimizing these stage parameters is to run a finite element analysis to determine the location and number of support points (e.g., Z actuators), location of linear bearings, and geometry and thicknesses of ridges to provide the desired stiffness and flatness.

FIG. 9D is a perspective bottom view of the multi-panel stage 900 with extra linking bars 816 between adjacently positioned stage blocks 912A, 912B to enhance the flatness of the stage by providing additional support and rigidity. The exemplary multi-panel stage 900 includes two linking bars 816A and 816B located at each end of the adjacently positioned stage blocks 812A and 812B as well as a third and fourth linking bars 816C and 816D positioned between the ends. In one embodiment, the multi-panel stage 900 is preferably configured to receive fifteen Z-actuators at a plurality of Z-actuator receptacles 826 in order to ensure a testing surface with requisite flatness. Linear bearing receptacles 918 may be provided to assist in ensuring unidirectional movement in the multi-panel stage 900. Ridges 920 that emanate outwardly from each individual Z-actuator receptacle 826, each linear bearing receptacle 918, and along the edges of each of the stage blocks 812A-812E provide strength and rigidity to the stage while minimizing the stage weight.

FIG. 9E shows a cross-sectional view of the multi-panel stage 900 along line E-E. At least one actuator receptacle 826 is shown, which may comprise a circular-shaped recess 922 configured to accommodate an upper end of a Z-actuator, and a circumferential ridge 924 configured to reduce lateral movement of the Z-actuator mounted therein. Also, ridges 920 that emanate from the actuator receptacles 826 are generally thicker near the receptacle 826 and taper in thickness along the length of the ridge. Other cross-sectional views of linking bars 816 along line F-F, linear bearing receptacles 918 along line G-G, and various size ridges 920 along line H-H are shown in FIGS. 9E through 9H, respectively.

FIGS. 9I and 9J are cross-sectional views of a Z-actuator 575 in a nominal down position and an extended up position, respectively, coupled to a multi-panel stage 800. At least one Z-actuator 575 is disposed in each of the actuator receptacles 826 of the multi-panel stage 800. Referring to FIG. 9I, the Z actuator 575 includes a lower flange 955 which is coupled to an upper stage 560 that is adapted to move in a horizontal direction. The Z actuator 575 further includes a disc-shaped mount 985 which is coupled to the back side of one of the stage blocks, for example stage block 812A. The interior of the Z actuator 575 comprises a shaft 975 connected at a lower end to a piston 965 and an annular hardstop 960, an O-ring 990, and a hardstop flange 950. The interior of the Z actuator 575 also contains a flexible bellows 980 arranged about the interior moving parts of the Z actuator 575 to minimize particle contamination therefrom. Finally, the Z actuator 575 utilizes air through an orifice 970, for example a ¼ VCR female nut and gland, to pneumatically move the piston 965 between up and down positions. The flexible bellows 980 expand and compress in response to the up and down movement of the Z actuator 575. When the Z actuator 575 is extended to an up position, the multi-panel stage 800 moves up vertically until the annular hardstop 960 contacts the hardstop flange 950, as depicted in FIG. 9J. A substrate 101 is shown on the multi-panel stage 800 and is lifted vertically to contact a prober disposed in the prober frame 310 coupled to a spacer 579.

In one mode of operation, the orifice 970 may be connected to a vacuum source to move the piston 965 downward to its nominal position, and vented to air at atmospheric pressure to move the piston 965 upward into its extended position. This mode of operation is most advantageous when the multi-panel stage 800 or 900 is used in a vacuum environment during testing. In one example, the Z actuator 575 is configured to have a vertical stroke of about 50 mm, a stroke time of about 2 seconds, and a net lifting thrust of about 15.5 kg.

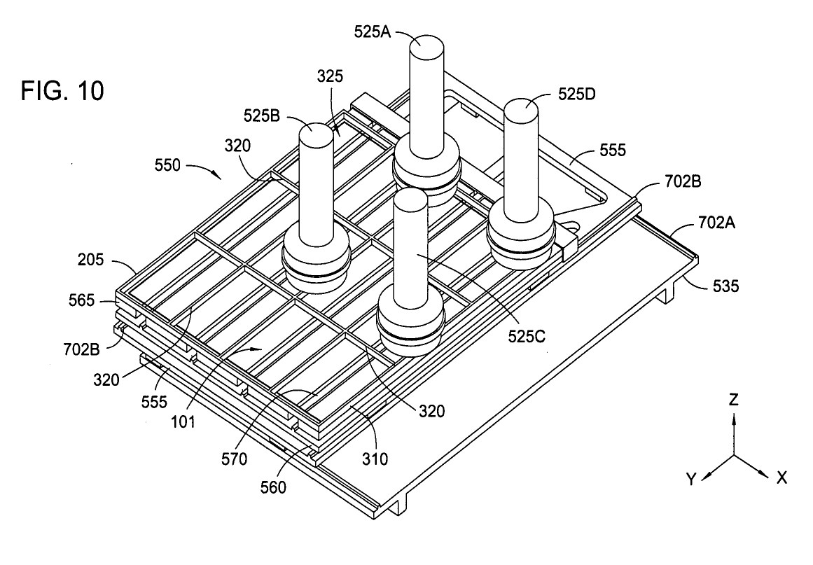

FIG. 10 shows a basic schematic plan view of the substrate support table 550, end effector 570, prober 205, Z-stage 565, and EBT columns 525A-525D. The housing 505 of the testing chamber 500 has been removed to more easily visualize the components of the multi-panel stage 550 in relation to the EBT testing columns 525A-525D. The multi-panel stage 550 is shown such that side 550A would be adjacent the prober transfer assembly 300 disposed toward the X direction and the side 550B would be adjacent the load lock chamber 400 disposed toward the Y direction.

As shown in this perspective, the lower stage 555 is disposed on the base 535 and moves along rails 702A. The upper stage 560 is disposed on the lower stage 555 and moves along rails 702B. The Z-stage 565 is disposed on the upper stage 560 and the end effector 570 is disposed therebetween. The substrate 101 is resting on the upper surface of the Z-stage 565 and abuts the lower surface of the prober 205.

In one example, a multi-panel stage, as depicted in FIGS. 9A and 9C, having a testing surface area greater than about 25,000 cm² was fabricated having dimensions of 1950 mm×1300 mm×125 mm (L×W×H), a weight of 116 kg, a flatness of +/−15 μm in any 380 mm diameter area and a flatness of +/−200 μm per quadrant of the testing surface, and a total stage deflection of 17 μm (due to gravity) when supported by ten Z stage lifts. To fabricate the multi-panel stage, each of the stage blocks were machined from five monolithic aluminum alloy starting blocks of 6061-T6 Al. After machining the five individual stage blocks to have the desired ridges, z-actuator receptacles, and linear bearing receptacles as depicted in FIG. 9C, the individual stage blocks were assembled together using twelve linking bars and the testing surface 810 of the stage blocks were ground to a flatness of +/−15 μm in any 380 mm diameter area and a flatness of +/−200 μm per quadrant of the testing surface using a cast tooling plate. The cast tooling plate was designed to mimic the ten Z actuator points of support to simulate when the multi-panel stage (i.e., stage weight) is supported by ten Z stage lifts. Afterwards, the top of the tooling plate was ground flat until all ten support points were in one plane. The multi-panel stage was then placed on the tooling plate and the top surface of the multi-panel stage was ground to the desired flatness specifications. This unique manufacturing method minimizes assembled stage deformation due to gravity in order to achieve the desired flatness specifications of the multi-panel stage when supported by Z stage lifts. Other tooling plates having a predetermined number (N) of support points may be utilized to grind the testing surface 810 of the stage blocks having N Z-stage lift points.

In another example, a multi-panel stage, as depicted in FIG. 9D, having a testing surface area greater than about 40,000 cm² was fabricated having dimensions of 2300 mm×2030 mm×125 mm (L×W×H), a weight of 162 kg, a flatness of +/−15 μm in any 380 mm diameter area and a flatness of +/−200 μm per quadrant of the testing surface, and a total stage deflection of 5.6 μm (due to gravity) when supported by fifteen Z stage lifts. To fabricate the multi-panel stage, each of the stage blocks were machined from five monolithic aluminum alloy starting blocks of 6061-T6 Al. After machining the five individual stage blocks to have the desired ridges, z-actuator receptacles and linear bearing receptacles as depicted in FIG. 2B, the individual stage blocks were assembled together using sixteen linking bars and the testing surface 810 of the stage blocks were ground to a flatness of +/−15 μm in any 380 mm diameter area and a flatness of +/−200 μm per quadrant of the testing surface. The assembled multi-panel stage was ground using a cast tooling plate designed to mimic the fifteen Z actuator points of support to simulate when the multi-panel stage (i.e., stage weight) is supported by fifteen Z stage lifts. Afterwards, the top of the tooling plate was ground flat until all fifteen support points were in one plane. The multi-panel stage was then placed on the tooling plate and the top surface of the multi-panel stage was ground to the desired flatness specifications.

Prober

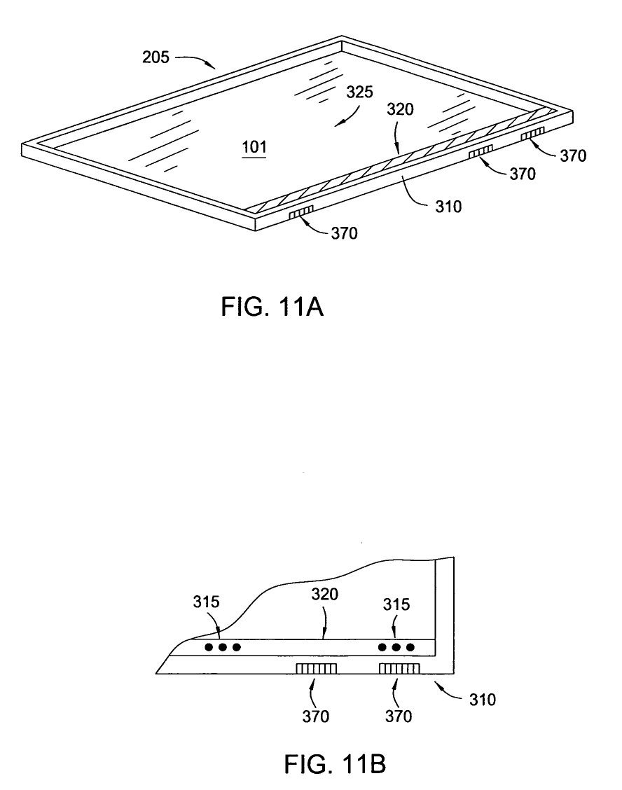

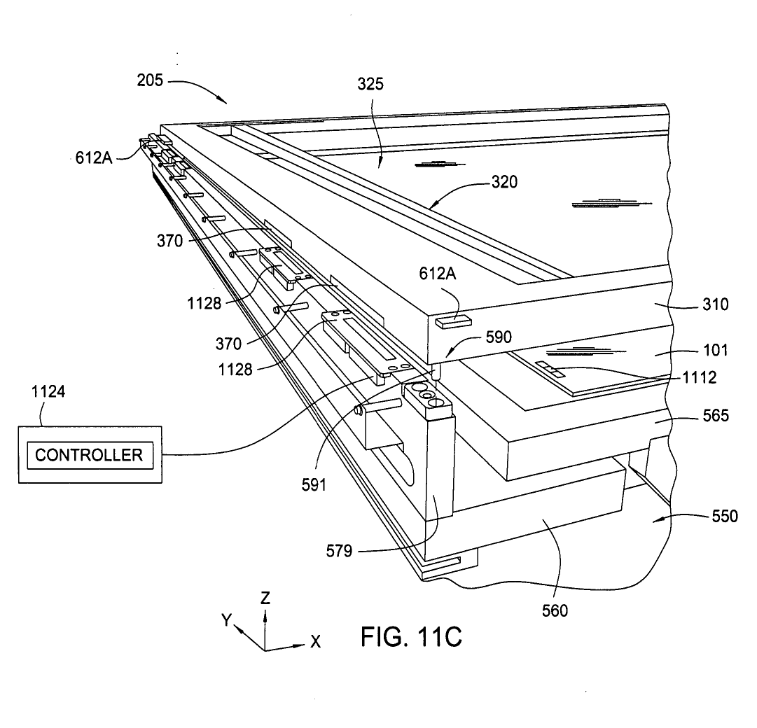

FIG. 11A is a perspective view of one embodiment of a prober 205. The prober 205 is adapted to assist in the testing sequence performed by the EBT system 100. The prober 205 has a generally rectangular frame 310 and includes one or more prober bars 320. In this embodiment, the prober bar 320 is coupled to the frame and is adapted to test a large area substrate 101 having one or more flat panel displays formed thereon. The area between the frame 310 and the prober bar 320 generally defines a test area 325 on the large area substrate 101. The test area 325 may be a large area flat panel display or a plurality of smaller flat panel displays located on the large area substrate 101, the display or displays having conductive contact areas placed thereon that are in electrical communication with one or more electronic devices. The conductive contact areas are not shown on the substrate 101 due to the small size, but allow the prober 205 to contact and be electrically coupled to the electronic devices on the substrate 101.

FIG. 11B is a partial plan view of the lower surface of the prober 205. A prober bar 320 is shown coupled to a prober frame 310. The prober bar 320 has a plurality of prober pins 315 that are in communication with one or more electrical connection blocks 370 that are adapted to couple to a controller through a mating connection coupled to the substrate support table 550 (not shown). The prober pins 315 are adapted to contact conductive contact areas on the substrate 101. These conductive contact areas on the substrate are in electrical communication with one or more devices on the substrate. The prober pins 315, in electrical communication with the controller, are configured to receive a signal from the controller that is transmitted to the devices on the substrate from the prober pins 315 during a testing sequence.

FIG. 11C is a partial perspective view of the prober 205 adjacent the upper stage 560. The prober 205 is configured to be positioned on a spacer 579 coupled to the substrate support table 550. The prober pins 315 (FIG. 11B) are adapted to contact a substrate 101 at locations corresponding with conductive contact areas 1112, which may be shorting bar contact points or contact pads placed on the substrate 101, when the prober 205 is moved adjacent to the substrate 101. The electrical connection blocks 370 on the prober 205 are adapted to mate with corresponding electrical mating blocks 1128 coupled to the substrate support table 550. The electrical mating blocks 1128 are in communication with a controller 1124 that supplies a signal that is ultimately communicated to the conductive contact areas 1112 on the substrate 101.

In one mode of operation, the controller 1124 transmits a signal to the electrical mating blocks 1128 that is transferred to the prober pins 315. The controller 1124 is coupled to the electrical mating blocks 1128 by a suitable cable (not shown) and the electrical mating blocks 370 couple to the electrical mating blocks 1128 by suitable connectors. The prober pins 315 are coupled to the electrical mating blocks 370 by electrical connections routed in and/or along the prober frame 310 and to the prober bar 320. When the prober 205 is proximal the substrate 101 and the prober pins 315 contact the corresponding conductive contact areas 1112 on the substrate, electrical signals may be communicated between the controller 1124 and the electronic devices disposed on the substrate 101 and coupled to the conductive contact areas 1112.

The prober 205 may include a pin assembly 590 adapted to releasably secure the prober frame 310 to the spacer 579. In one embodiment, the pin assembly 590 can include a spring loaded pin 591 disposed within a recess formed in the prober frame 310. The pin 591 extends into a mating receptacle machined into the spacer 579, thereby securing the prober 205 to the substrate table 550. In another embodiment, the pin assembly 590 may not be spring loaded and a pin 591 may be coupled to the spacer 579, the pin 591 extending into a mating receptacle formed in the prober frame 310, thereby securing the prober 205 to the substrate table 550. In another embodiment, the pin 591 may be coupled to the prober frame 310 and extend into a mating receptacle formed in the spacer 579.

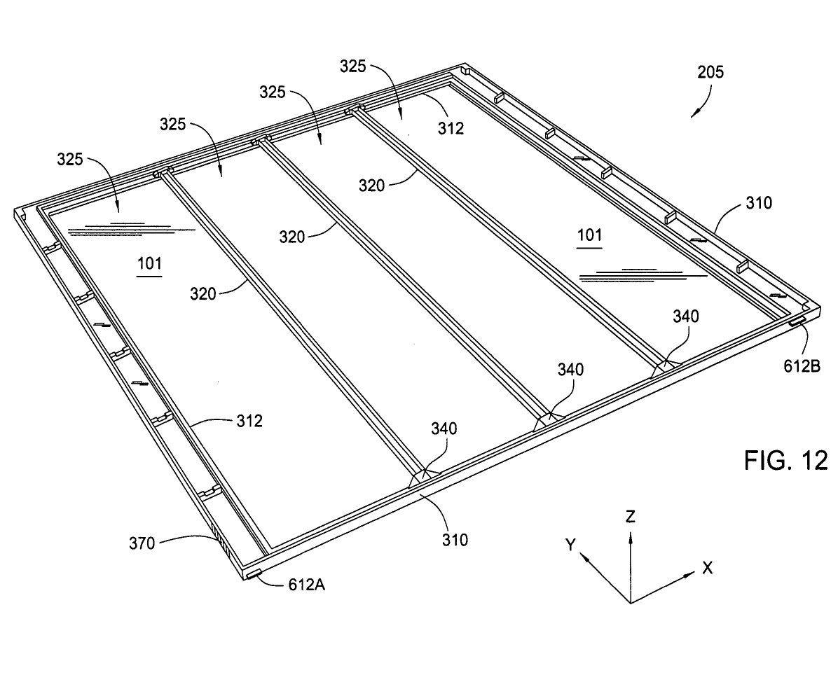

FIG. 12 is an isometric view of another embodiment of a prober 205 having three prober bars 320 positioned at selected coordinates along the X direction, and are parallel to the Y direction. In another embodiment, the prober 205 may also be configurable, meaning that the prober bars 320 may be moved and repositioned within the prober frame 310 to adapt to various conductive contact area configurations on the substrate or multiple displays having various contact pad configurations. Alternatively or additionally, the prober bars 320 may have variously shaped probe heads (not shown) that are releasably coupled along the prober bars 320 to adapt to various conductive contact area and display configurations. The prober bars 320 along the frame 310 may also be changed to adapt for different device layouts and substrate sizes. In order to change the position of the prober bars 320, the connection between the respective prober bars 320 and the frame 310 is releasable and relocatable. To provide for this feature, a frame connection mechanism 312 is provided that allows for relocation of at least one prober bar 320 on the frame 310 at selected coordinates along the Y direction of the frame. In one embodiment, the frame connection mechanism 312 is a plurality of through-holes placed along or formed within the inner surface of the frame 310. An end cap 340 may be provided to further secure the prober bars 320 to the frame 310. In any of the above embodiments, the prober pins disposed on the prober bars 320 may also be movable to adapt to a user defined contact pad configuration of a substrate or flat panel display. Examples of suitable probers that may be used are disclosed in U.S. patent application Ser. No. 10/889,695, entitled “Configurable Prober for TFT LCD Array Testing,” filed Jul. 12, 2004, and U.S. patent application Ser. No. 10/903,216, entitled “Configurable Prober for TFT LCD Array Test,” filed Jul. 30, 2004, both applications incorporated by reference herein. In order to transfer probers 205 into and out of the testing chamber 500, a prober transfer assembly 300 is used.

Prober Transfer Assembly

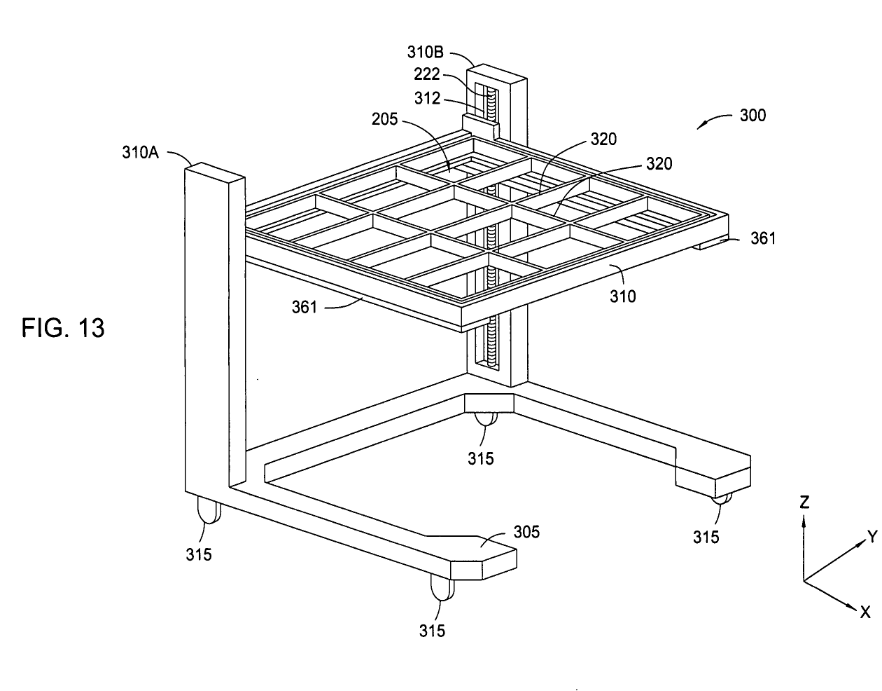

FIG. 13 shows a schematic isometric view of one embodiment of the prober transfer assembly 300. The prober transfer assembly 300 is a modular unit disposable near the testing chamber 500 for transferring a prober 205 between the prober storage assembly 200 and the testing chamber 500. The prober transfer assembly 300 includes a base 305 connected to two or more vertical support members 310A, 310B. Wheels 315 may be arranged on a bottom surface of the base 305 to easily maneuver the assembly 300 when desired. The prober transfer assembly 300 further includes a lift arm 361 that is attached at one end thereof to the support members 310A, 310B. The support members 310A, 310B each include a recessed track 312 for mating engagement with the lift arm 361. One or both of the recessed tracks 312 may house a drive motor 222. The recessed tracks 312, working in conjunction with the drive motor 222, guide and facilitate the vertical movement of the lift arm 361. The lift arm 361 is configured to be inserted into the testing chamber 500 or within the storage assembly 200 to retrieve and deliver the prober 205. The prober transfer assembly 300 may also receive one or more probers from other locations adjacent the test system 100.

The prober transfer assembly 300 may retrieve a prober 205 in many different ways. One example involves manual insertion of the lift arm 361 into the prober storage assembly 200. The prober storage assembly 200 may have a lifting device to engage a prober 205 and facilitates placement of the prober on an upper surface of the lift arm 361. The prober transfer assembly 300 may then be guided manually out of the storage assembly 200 with a prober 205 thereon. Alternatively, the prober 205 may be arranged and supported by the prober storage assembly 200 in a manner that allows insertion of the lift arm 361. The drive motor 222 may then be energized to lift and support the prober 205 on an upper surface of the lift arm 361, which may be guided out of the storage assembly 200. Another example involves maneuvering a skid assembly 160 (FIG. 1) out of the prober storage assembly 200 to a position on the floor where a lifting device, such as a facility crane, has access to the prober 205. The facility crane may then lift the prober 205 from the skid assembly 160 and position the prober on an upper surface of the lift arm 361.

Prober Z Lift

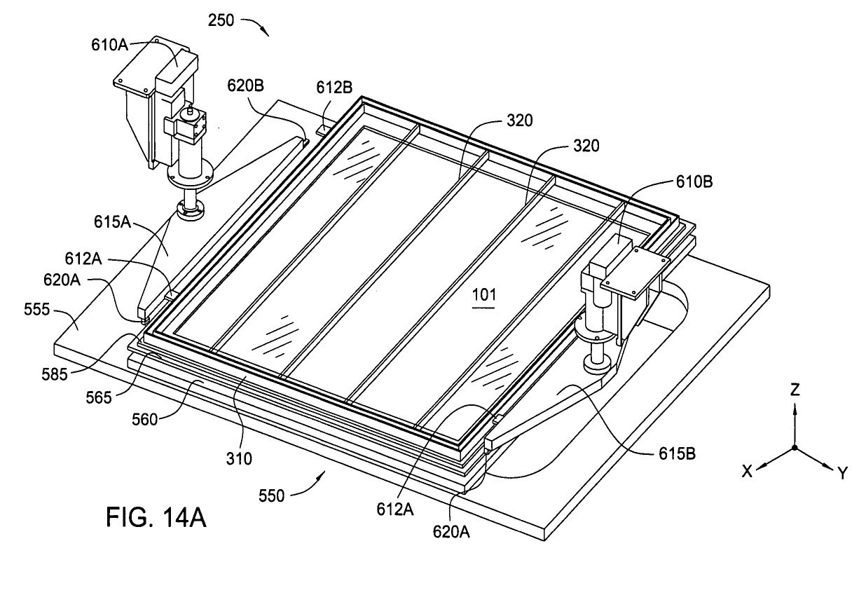

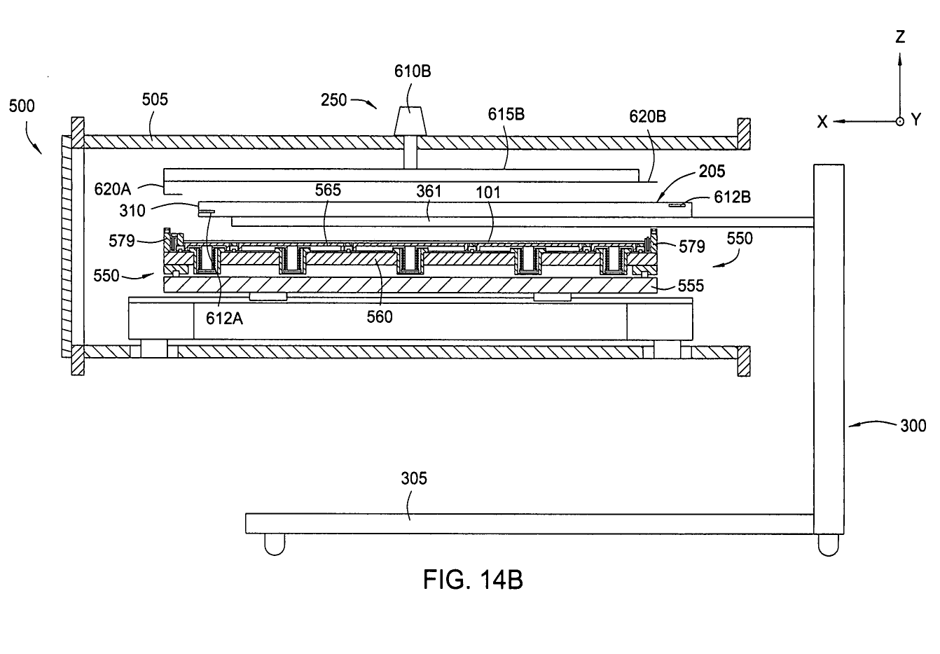

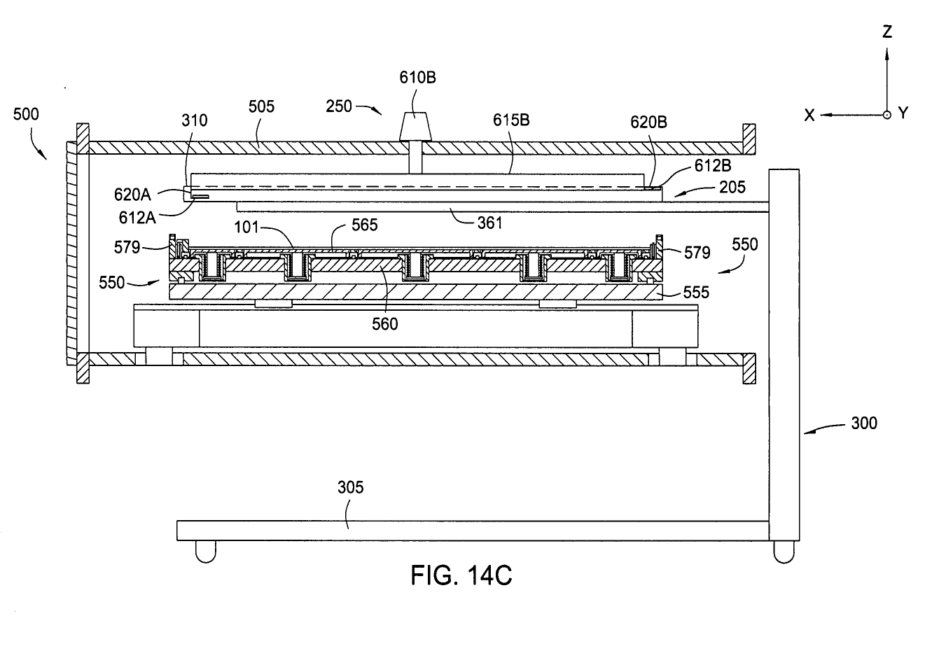

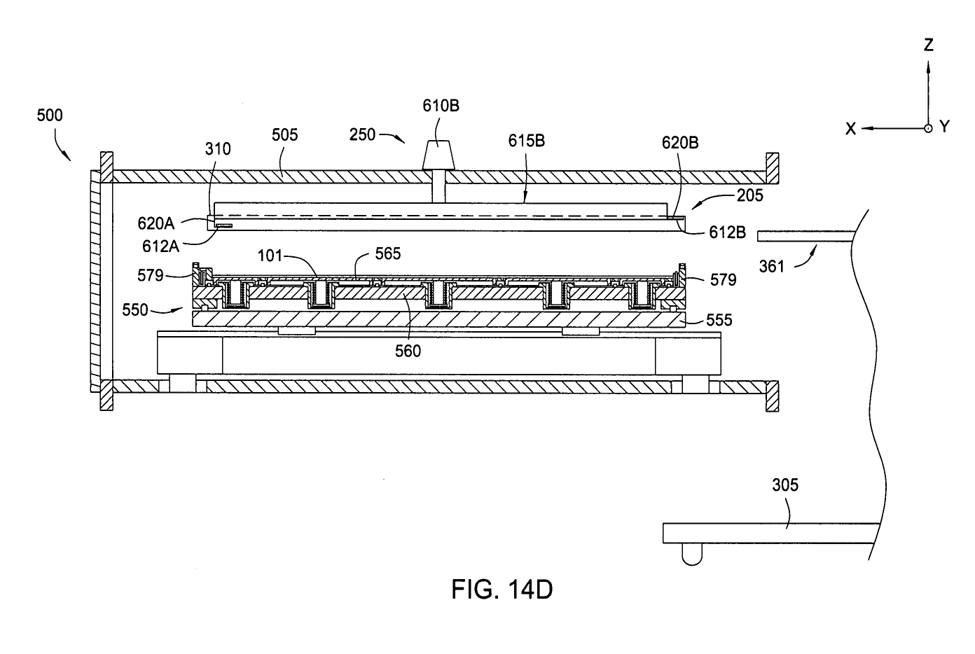

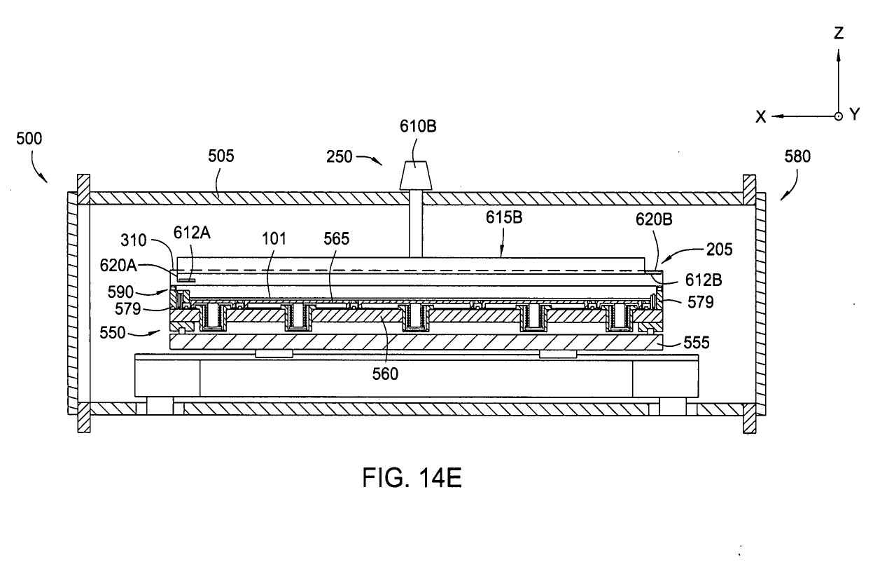

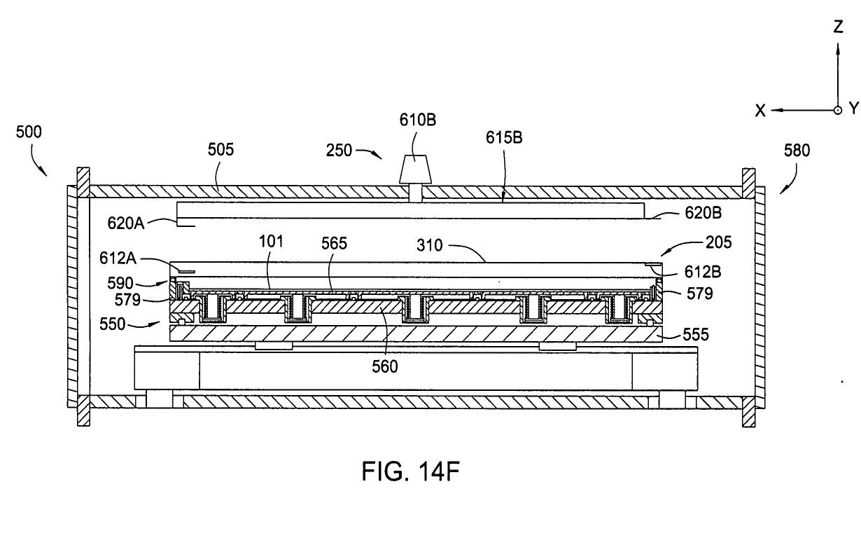

FIG. 14A shows an isometric view of a prober positioning assembly 250 that in one embodiment facilitates transfer and positioning of the prober 205 in the testing chamber 500. The prober positioning assembly 250 includes at least two Z actuators 610A and 610B that are typically coupled to an upper portion of the testing chamber 500 above the substrate support table 550. The prober positioning assembly 250 includes at least two lift members 615A and 615B that are coupled to the at least two Z actuators 610A and 610B. Each of the lift members 615A, 615B include at least two frame support tabs 620A and 620B that are adapted to releasably engage at least two prober support tabs 612A and 612B coupled to the prober frame 310. The prober positioning assembly 250 is adapted to provide movement in Z direction of the prober frame 310 relative to any directional movement of the substrate table 550.

FIG. 14B is a schematic view of the prober positioning assembly 250 in the interior of the chamber body 505 above the substrate table 550. A prober 205 and a prober frame 310 are supported by at least one lift arm 361 coupled to the prober transfer assembly 300. The lift arm 361, with the prober frame 310 thereon, is shown partially inside the interior of the testing chamber 500. The lift member 615B has at least two frame support tabs 620A and 620B adapted to releasably engage the prober support tabs 612A and 612B. The frame support tabs 620A, 620B are shown in this view on opposing end surfaces of the lift member 615B for clarity, but the support tabs could be coupled to any surface of the lift member 615B. Both the frame support tabs 620A, 620B and the prober support tabs 612A, 612B are in a spaced apart relation in the X direction to allow stable support of the prober frame 310 during transfer. The frame support tabs 620A, 620B and the prober support tabs 612A, 612B are offset in a Z direction to allow the frame support tab 620B to clear the prober support tab 612A during transit of the prober frame 310 in the X direction.

In operation, the lift member 615B and the prober frame 310 may be substantially in the same plane in the Z direction for engaging the frame support tabs 620A, 620B and the prober support tabs 612A, 612B. During transit in the X direction, the lower position of prober support tab 612A allows the prober support tab 612A to pass below the frame support tab 620B and the frame support tab 620A will be in a position to act as a stop for the prober frame 310 when the prober support tab 612A is adjacent the frame support tab 620A as shown in FIG. 13C.

FIG. 14C is a schematic plan view of the prober frame 310 in a position for transfer to the prober positioning assembly 250. The frame support tabs 620A, 620B and the prober support tabs 612A, 612B are in a position to engage when the prober frame 310 has been moved in the X direction a desired distance. The prober positioning assembly 250 may now be actuated upward in a Z direction to lift the prober frame 310 from the prober transfer assembly 300. When supported and the prober frame 310 is lifted from the prober transfer assembly 300, the prober transfer assembly 300 may be extracted from the testing chamber 500.

FIG. 14D is a schematic plan view of the prober frame 310 supported by the prober positioning assembly 250, thus allowing the prober transfer assembly 300 to exit the chamber. The prober positioning assembly 250 may now be actuated downward in a Z direction to contact an upper surface of the substrate support table 550. More specifically, the prober frame is actuated downward to contact a spacer 579 coupled to the substrate support table 550 as shown in FIG. 14E.

FIG. 14E is a schematic plan view showing the prober frame 310 supported by the spacer 579 disposed on opposite ends of the substrate support table 550. Once in contact with the upper surface of the substrate support table 550 and positioned on the spacer 579, the prober positioning assembly 250 continues to be actuated downward to allow the frame support tabs 620A, 620B to be spaced apart vertically from the prober support tabs 612A, 612B. Once the frame support tabs 620A, 620B and the prober support tabs 612A, 612B are spaced apart vertically, the lower stage 555 or the upper stage 560 is actuated in an X or Y direction respectively. This horizontal movement may be a very small increment, such as 1 inch, to allow the frame support tabs 620A, 620B and the prober support tabs 612A, 612B to be spaced apart horizontally. Once the frame support tabs 620A, 620B and the prober support tabs 612A, 612B are a sufficient distance apart horizontally, the prober positioning assembly 250 is actuated upward in a Z direction to a position above the substrate support table 550 so as to not interfere with any movement of the substrate support table 550 during testing or substrate transfer.

FIG. 14F shows the prober frame 310 and the prober 205, resting on the spacer 579 disposed on an upper surface of the upper stage 560 and the prober positioning assembly 250 in a vertical position that does not interfere with any movement of the substrate support table 550. The prober frame 310 may be releasably secured to the spacer 579 using a pin assembly 590 (FIG. 11C). The movable sidewall 580 may be actuated and positioned to seal the chamber body 505, and the Z stage 565, with the substrate 101 thereon, may be actuated vertically to contact the prober 205. Once the testing chamber 500 is at a suitable pressure and the prober 205 is contacting the substrate 101, a testing sequence may commence.

Prober Exchanger

Referring again to FIG. 2, an alternative embodiment of a prober transfer assembly such as a prober exchanger 350 will be described. The prober exchanger 350 is configured to increase flat panel display testing throughput by combining a prober transfer mechanism with temporary prober storage. For instance, if a user is currently testing a product in the testing chamber 500, for example a substrate having a plurality of 17 inch flat panel displays, and desires to test another product, for example a substrate having a plurality of 40 inch displays, a different prober 205 may be needed. The time to remove the prober needed for the plurality of 17 inch displays and transfer another prober capable of testing a plurality of 40 inch displays is typically greater than the time needed to unload and load a particular substrate in the testing chamber 500. Thus, the prober exchanger 350 minimizes the prober transfer time by allowing pre-loading of a differently configured prober and storing the prober on the prober exchanger 350 until needed.

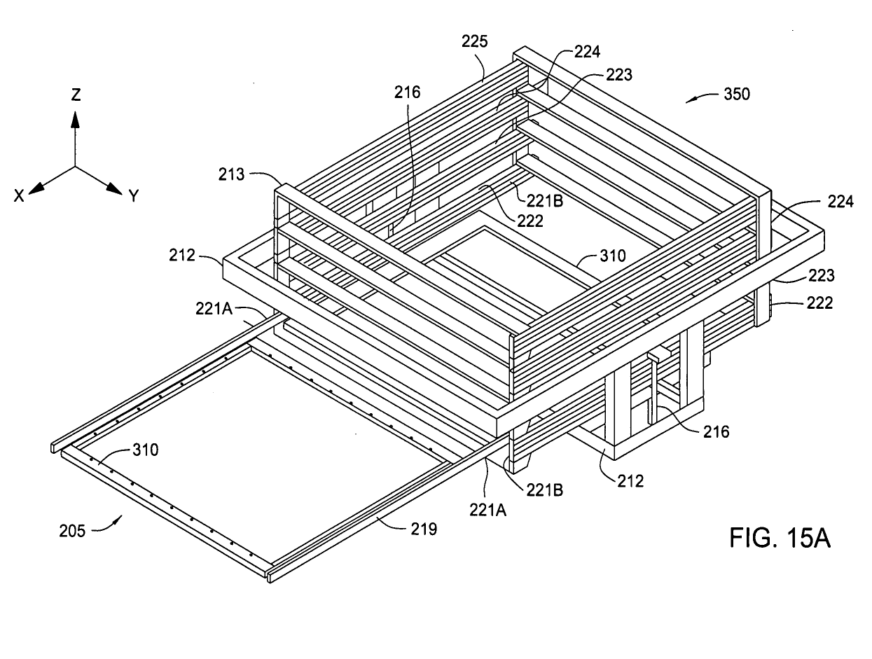

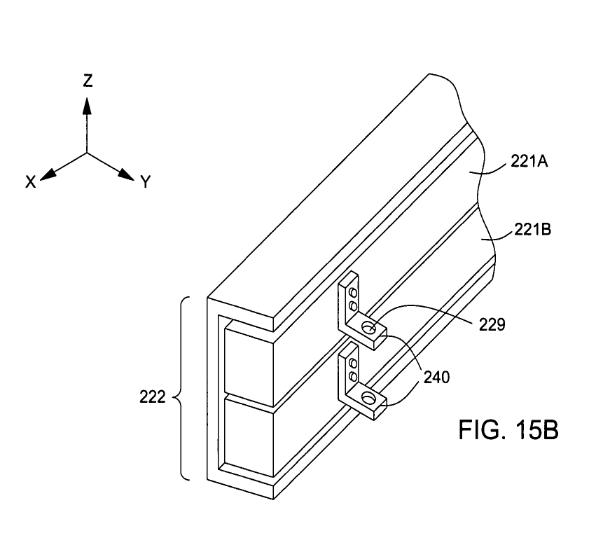

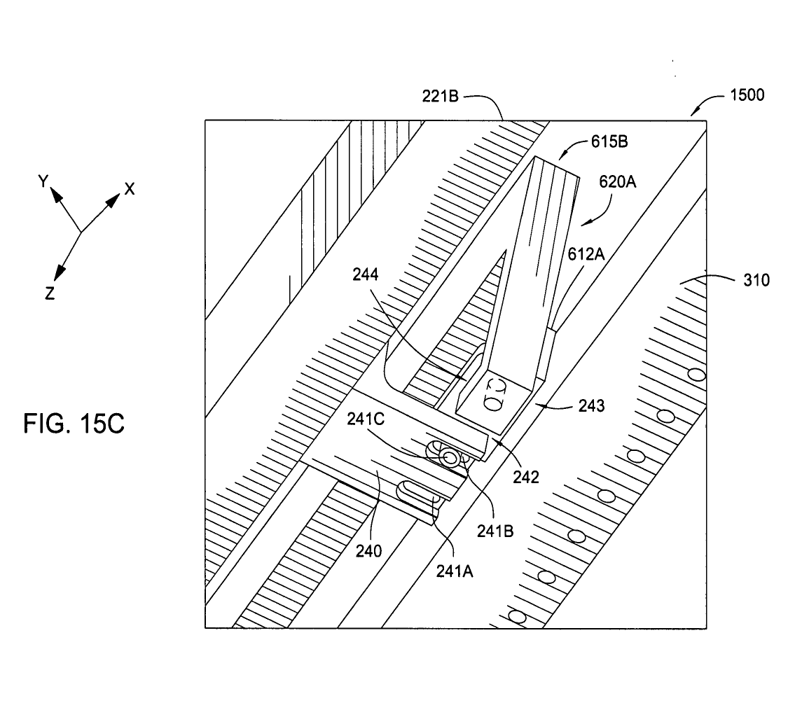

In one embodiment, the prober exchanger 350 has an outer frame 212 that is supported on one end on the testing chamber 500, and the opposite end supported by outer supports 214. The outer frame 212 is sized to receive an inner frame 213 (FIG. 15A) that serves as the prober temporary storage and transfer mechanism. In operation, the inner frame 213 is capable of vertical (Z direction) movement by a vertical actuator 216 that provides vertical movement to the inner frame 213 relative the outer frame 212.

FIG. 15A shows an isometric detail view of the outer frame 212 of the prober exchanger 350 coupled to the inner frame 213. The inner frame 213 is a polygonal structure that includes a transfer member support 222, transfer member support 223, transfer member support 224, and transfer member support 225 that defines a plurality of prober apertures. Each transfer member support 222, 223, 224, 225 has two transfer arms sized and configured to receive at least one prober frame 310. The inner frame 213 having the transfer member supports 222, 223, 224, 225 coupled thereto is capable of vertical (Z direction) movement by the vertical actuator 216 that provides vertical movement to the inner frame 213 relative the outer frame 212. The transfer arms are adapted to extend horizontally from the inner frame 213 in laterally and retract into the inner frame 213 after extension. The inner frame 213 or the transfer arms may be actuated in a horizontal X direction by another drive disposed within or adjacent the inner frame 213, or the vertical and horizontal movement may be accomplished by an actuator or set of actuators that are capable of providing X direction and Z direction movement to the prober exchanger 350. In this example, the inner frame 213 is actuated vertically by the at least one vertical actuator 216 and each transfer arm of each transfer member support 222, 223, 224, 225 is actuated horizontally by manual means, such as by an operator. The movement of the transfer arms may also be automated by using an actuator. At least one prober 205 disposed within the prober frame 310 may be positioned in one of the transfer arms of the transfer member supports and supported by the transfer arm associated with that transfer member support while the other transfer member in the transfer member support may be unused. For example, one prober 205 may be positioned on transfer member 221A of transfer member support 222 while transfer member 221B is left vacant, or one prober 205 may be positioned in transfer member 221B of transfer member support 222 while transfer member 221A is not used. As will be explained below, one transfer member of the transfer member supports 222, 223, 224, 225 receives a prober for temporary storage and transfer into and out of the testing chamber 500 while the other transfer member of the transfer member supports 222, 223, 224, 225 is left vacant to receive a prober from the testing chamber 500.

FIG. 15B is an isometric detail view showing one end of the transfer member support 222 having a transfer member 221A which defines an upper portion of transfer support member 222 and a transfer member 221B which defines a lower portion of transfer support member 222. Each of the transfer members 221A, 221B has at least two prober braces 240 that are configured to support a prober frame 310 thereon. The at least two prober braces 240 may have at least one mating mechanism that is adapted to mate with the prober support tabs 612 disposed on the prober frame 310 that may have a protrusion such as a pin 243 (FIG. 15C) adapted to engage the slot 229. Once one of the transfer members 221A, 221B is extended into the testing chamber 500 having the prober frame 310 thereon, the prober support tabs 612 interface with lift members 615A, 615B of FIG. 14A.

In operation, a user may attach a prober frame 310 having a selected prober 205 thereon from the skid assembly 160 (FIG. 1) to a facility lifting device such as a crane. The prober frame 310 with the selected prober 205 is introduced into the inner frame 213 (FIG. 15A) from a position above the prober exchanger 350, although other introduction paths are contemplated, such as introduction from a side or bottom of the prober exchanger 350. The prober frame 310 attached to the crane is positioned into the first available transfer member support from the top, which in this example is transfer member support 222. More particularly, the prober frame 310 having the selected prober 205 is positioned on transfer member 221B, the lowermost transfer member of transfer member support 222 and disconnected from the crane. Alternatively, the prober frame 310 having the selected prober 205 may be placed on transfer member 221A, the uppermost transfer member of transfer member support 222. The inner frame 213 of the prober exchanger is not limited to the four transfer member supports shown and may have any number of transfer member supports similar to transfer member supports 222, 223, 224, 225 and an appropriate number of prober frames 310 having selected probers 205 may be introduced into the transfer member supports as described above in a sequence defined by the user.

The operation of the transfer sequence of the prober exchanger 350 is similar to the operation described in FIGS. 14A-14F. Once the prober frame 310 is placed in the appropriate transfer member, such as transfer member 221B, and the prober frame 310 is supported by the interaction of the prober braces 240 and the prober support tabs 612, transfer member 221B may be extended laterally out of the inner frame 213 into the interior of the testing chamber 500. This operation is similar to the description of FIG. 14B except that the lift arms 361 of the prober transfer assembly 300 are replaced by the transfer member 221B. The transfer member 221B may travel horizontally and stop when the prober support tabs 612 are adjacent the frame support tabs 620 similar to FIG. 14C.

FIG. 15C is a partial isometric bottom view of an exemplary exchanger transfer interface 1500. The transfer interface 1500 includes a prober support tab 612A coupled to a prober frame 310 and adjacent a frame support tab 620A coupled to a lift member 615B. The lift member 615B is coupled to the prober positioning assembly 250 as shown in FIGS. 14A-14F. The transfer arm 221B is extended out of the outer frame 212 into the testing chamber while supporting the prober frame on the prober brace 240. The prober brace 240 may include at least one transfer indexing member 241A, 241B, which may be slots configured to receive a pin 241C coupled to the prober support tab 612A. The transfer indexing member 241A, 241B is configured to align and stabilize the prober frame 310 during transfer. The transfer arm 221B transports the prober frame 310 in an X direction to bring the prober support tab 612A in close proximity to the frame support tab 620A.

One of the lift member 615B or the prober frame 310 may include a lift indexing member 244 which may be a protrusion 243 coupled to the frame support tab 620A that is adapted to mate with an opening (not shown) formed in the prober support tab 612A. Alternatively, the prober support tab 612A may have an indexing pin that is adapted to mate with an opening formed in the frame support tab 620A. The lift indexing member 244 is configured to provide an aligning and a stabilization feature as the prober frame 310 is coupled to the prober positioning assembly 250.

Once the prober frame 310 has traveled a desired distance into the chamber and is adjacent the lift member 615B, the prober positioning assembly 250 may be actuated vertically upward to engage the frame support tab 620A and the prober support tab 612A. As the upward vertical actuation (Z direction) of the prober positioning assembly 250 continues, the prober frame 310 is supported by the lift member 615B and is disengaged from the prober brace 240. Once disengaged from the prober brace 240, the transfer arm 221B may be laterally retracted into the outer frame 212 and out of the chamber. The lift member 615B may be actuated vertically downward by the prober positioning assembly 250 and the prober frame 310 may be lowered on to the spacer 579 above the substrate support table 550. The spacer 579 will provide a support for the prober frame 310 and the lift member 615B may be actuated vertically downward by the prober positioning assembly 250 to lower the lift member 615B and disengage the prober support tab 612A from the frame support tab 620A. The lift member 615B may continue in the Z direction until the frame support tab 620A and the prober support tab 612A are spaced apart vertically. When there is sufficient vertical spacing between the frame support tab 620A and the prober support tab 612A, the lower stage 555 or the upper stage 560 is actuated in an X or Y direction respectively. This horizontal movement may be a very small increment, such as 1 inch, to allow the frame support tabs 620A, 620B and the prober support tabs 612A, 612B to be spaced apart horizontally. Once the frame support tabs 620A, 620B and the prober support tabs 612A, 612B are a sufficient distance apart horizontally, the prober positioning assembly 250 is actuated upward in a Z direction to a position above the substrate support table 550 so as to not interfere with any movement of the substrate support table 550 during testing or substrate transfer.

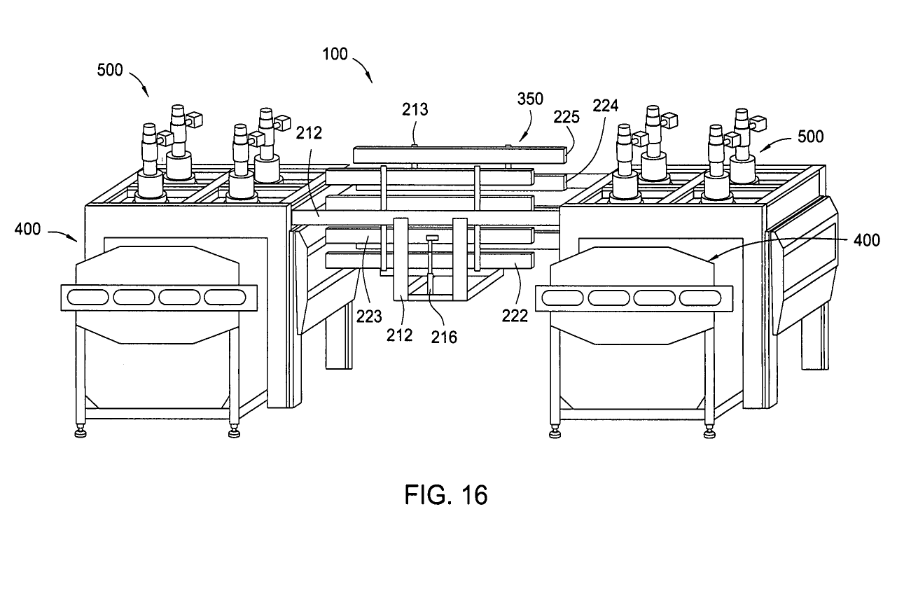

FIG. 16 is an isometric view of another embodiment of a test system 100 adapted to increase testing throughput of large area substrates. The test system 100 has two testing chambers 500, 500, coupled to two load lock chambers 400, 400, respectively. A prober exchanger 350 is coupled to the testing chambers 500, 500 and may facilitate transfer of one or more probers between each of the testing chambers.

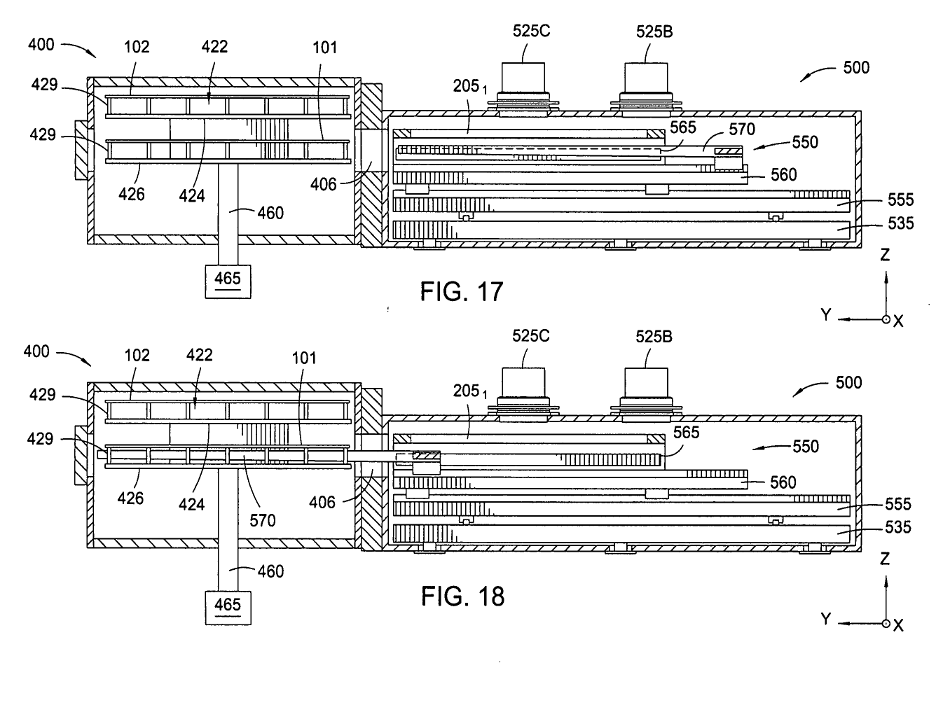

FIGS. 17-30 are partial cross-sectional views of one embodiment of the load lock chamber 400 and the testing chamber 500 illustrating an operational sequence. In an exemplary operation, a substrate 101, e.g., a plurality of 17 inch displays, and a substrate 102, e.g., a plurality of 40 inch displays, may be in the load lock chamber 400 subsequent an atmospheric loading operation that transfers the substrates 101, 102 into the load lock chamber 400. During this atmospheric loading operation, the user may attach a prober frame 310 having a selected prober 205 thereon capable of testing substrate 102. Alternatively, the user may load the prober 205 at any time before, during, or after testing. In this exemplary description, the prober frame 310 with the selected prober 205 is loaded during the atmospheric loading operation to use time more efficiently and the prober 205 is introduced into the slot from a position above the prober exchanger 350 by a facility crane. The prober frame 310 attached to the crane is positioned into the first available transfer member support from the top, which in this example is transfer member support 222. More particularly, the prober frame 310 having the selected prober 205 is positioned in transfer member 221B, i.e., the lowermost transfer member of transfer member support 222 and disconnected from the crane.

In this exemplary operation, a prober ²⁰⁵¹, capable of testing substrate 101 has been transferred and positioned above the substrate support table 550. FIG. 17 shows the Z-stage 565 in a substrate transfer position to transfer the substrate 101 from the load lock chamber 400 to the testing chamber 500 through a slit valve 406. The substrate 101 is disposed on an upper surface of the support tray 426 and is positioned in a transfer position by the lift actuator 465 coupled to the dual slot substrate support 422.

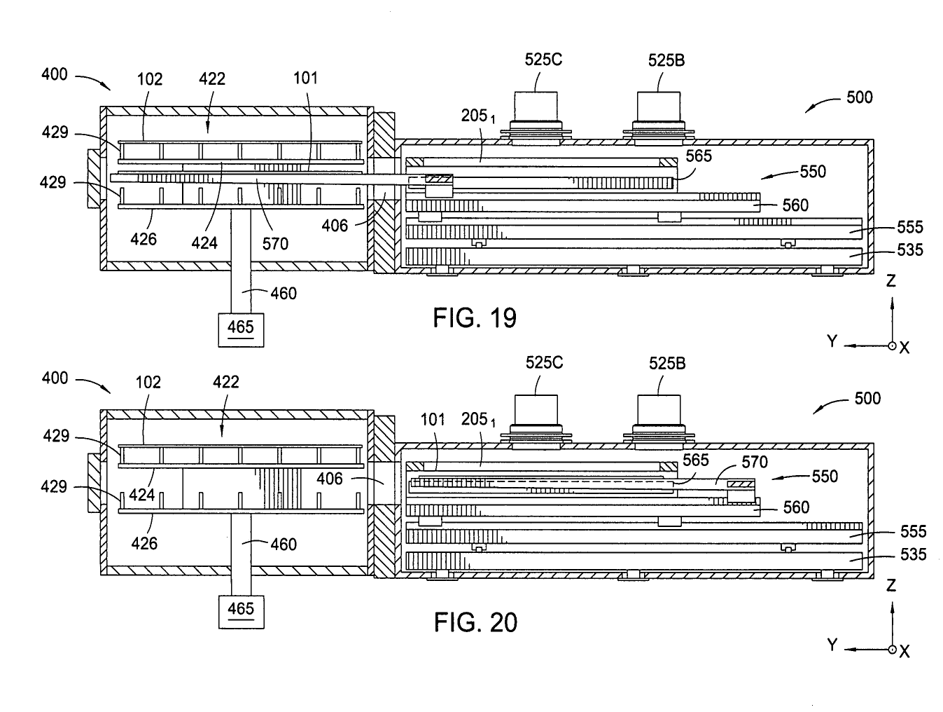

FIG. 18 shows the end effector 570 extending from the Z-stage 565 to a position below the substrate 101. FIG. 19 shows the end effector 570 contacting and supporting the substrate 101 and the dual slot substrate support in a lower position, thereby allowing the end effector 570 to support and transfer the substrate 101 into the testing chamber 500.

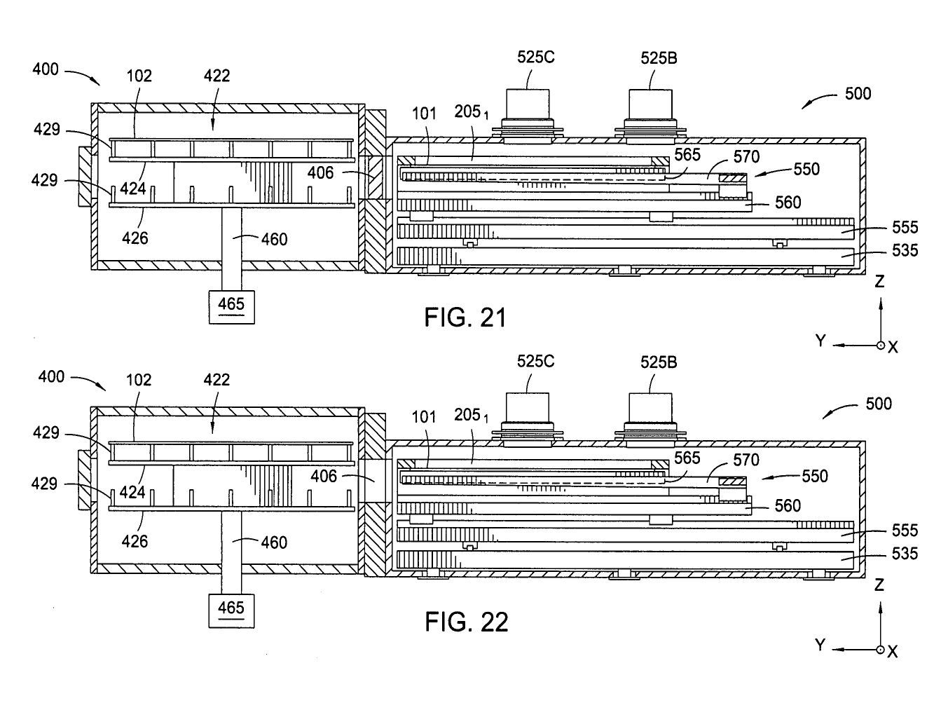

FIG. 20 shows the substrate 101 supported by the end effector 570 within the testing chamber 500. FIG. 21 shows the slit valve 406 closed isolating the testing chamber 500 from the load lock chamber 400. The testing chamber 500 may be pumped down to a lower pressure and the Z-stage 565 may be raised above the fingers of the end effector 570 to support the substrate 101 and provide contact between the prober 205₁ and the conductive contact areas on the substrate. Once contact is made and a signal provided to the probe pins on the prober 205₁, the lower stage 555 and the upper stage 560 may move linearly in their respective directions to place discrete portions of the substrate 101 beneath at least one of the EBT columns 525A-525D for a testing sequence.

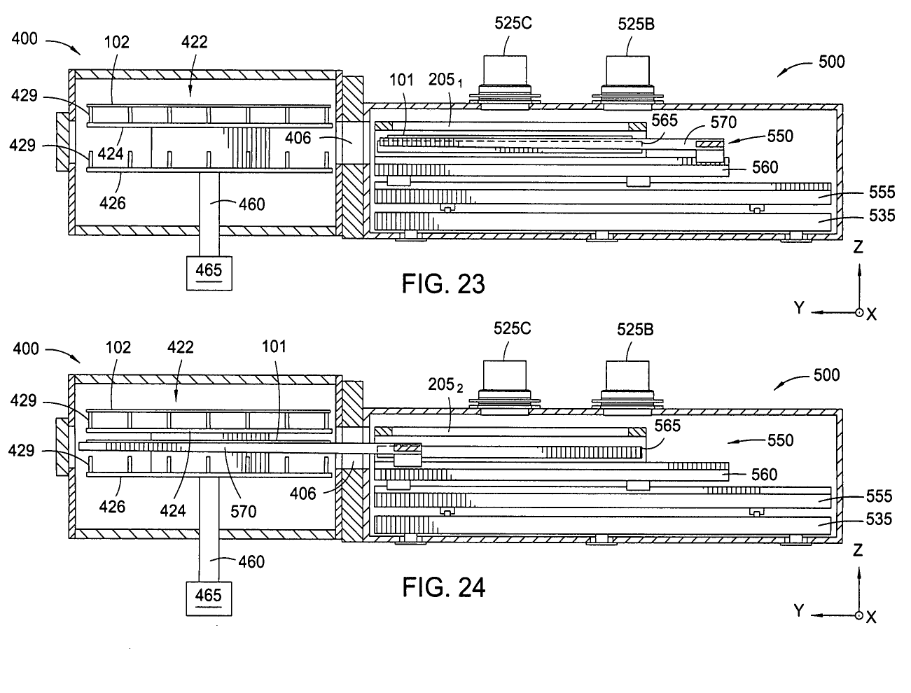

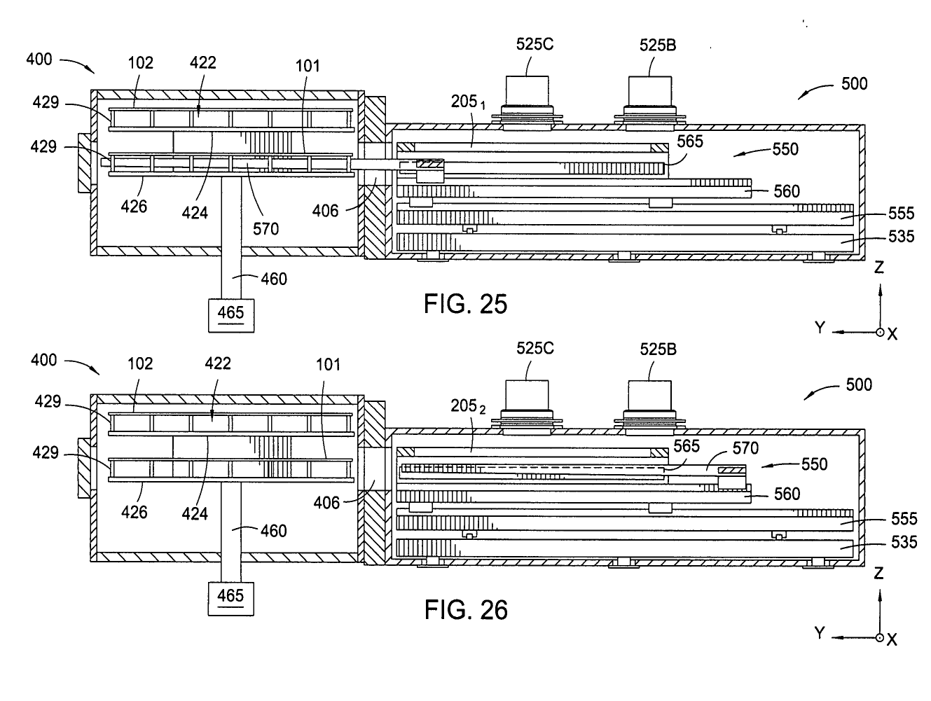

Subsequent a testing sequence being completed on substrate 101, the substrate support table 550 is moved to a substrate transfer position within the testing chamber 500 as shown in FIG. 22. FIG. 23 shows the Z-stage 565 lowered to allow the fingers of the end effector 570 to support the substrate 101. FIG. 24 shows the end effector 570 extended into the load lock chamber 400 through the slit valve 406 to transfer the substrate 101 to the support tray 426 as shown in FIG. 25.

A prober transfer step may be executed at any point during the substrate transfer operation, except during the testing sequence, or when the testing chamber 500 is under vacuum. It may be preferable to perform the prober transfer when the testing chamber 500 is without a substrate which may reduce particle contamination and advantageously uses time, thus increasing throughput since the substrate transfer and prober transfer are executed at the same time. To execute prober transfer, the testing chamber 500 may be vented down to atmospheric conditions and the movable sidewall 580 may be opened. Since substrate 101 has been tested and substrate 102 is next, the prober 205₂ is replaced by the prober 2052 for the next testing sequence. Substrate 102 may be in the load lock chamber 400 ready for introduction to the testing chamber as shown, or, alternatively, an atmospheric substrate transfer sequence may occur to load the substrate 102 into the load lock chamber 400.

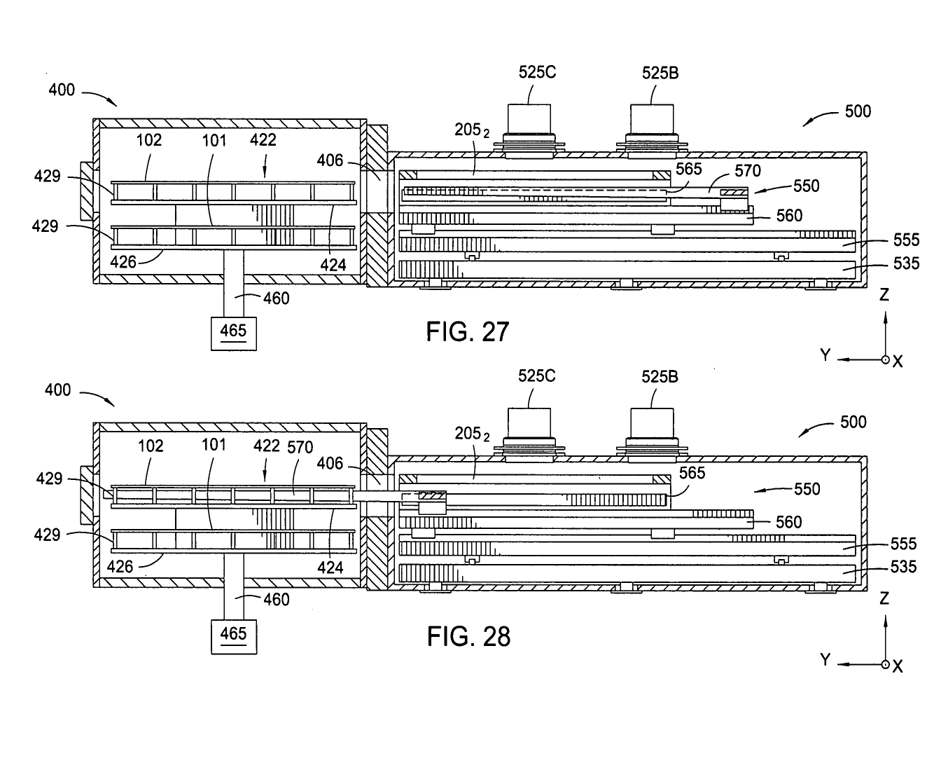

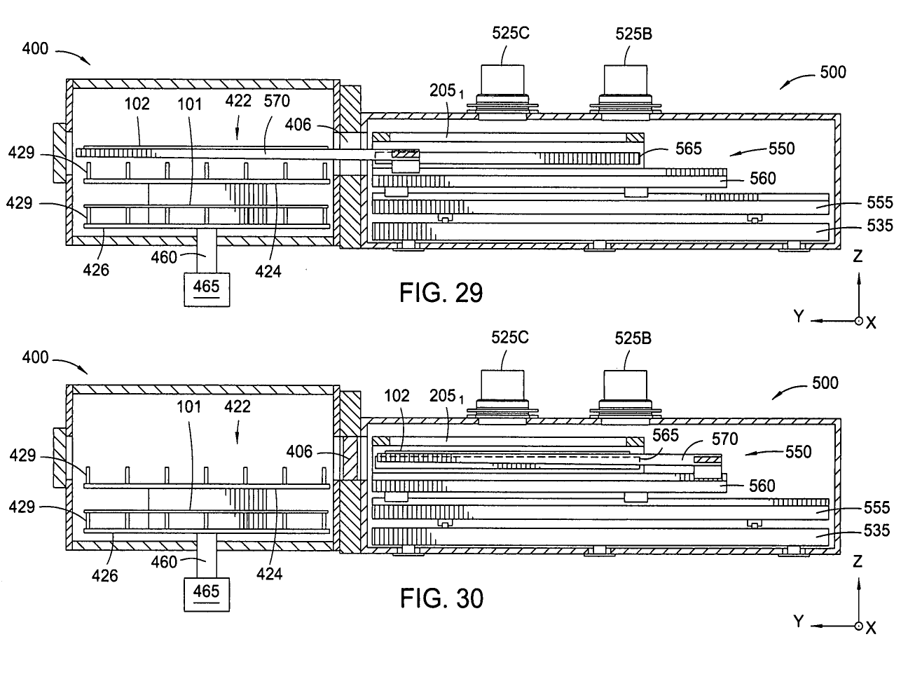

FIG. 26 shows the end effector 570 retracted into the testing chamber to allow the lift actuator 465 to position the dual slot substrate support 422 for transferring substrate 102 into the testing chamber 500. FIG. 27 shows substrate 102 in a plane for transfer to testing chamber 500. The end effector 570 then extends to a position below the substrate 102 as shown in FIG. 28. FIG. 29 shows the substrate 102 supported by the fingers of the end effector 570 and the end effector then retracts to transfer the substrate. FIG. 30 shows the end effector 570 retracted into the testing chamber 500. The slit valve 406 may be closed and the testing chamber 500 may be pumped down to a suitable pressure. The Z stage 565 may be actuated above the end effector 570 to support the substrate 102 and bring the substrate 102 into contact with the prober 205₂, similar to the embodiment shown in FIG. 21. A testing sequence may now occur on substrate 102 and the process described may continue.

While the foregoing is directed to embodiments of the present invention, other and further embodiments of the invention may be devised without departing from the basic scope thereof, and the scope thereof is determined by the claims that follow.

1. A chamber for processing a substrate, comprising:
a top;
a bottom;
at least one rigid sidewall coupled to the top and the bottom;
a movable sidewall, wherein the top, the bottom, the rigid sidewall, and the movable sidewall define an interior region in fluid communication with a vacuum pump; and
at least one actuator to move the movable sidewall between an open position and a closed position, wherein the interior region is in communication with atmospheric conditions when the movable sidewall is in a open position.

2. The chamber of claim 1, wherein the movable sidewall comprises:
an aluminum material.

3. The chamber of claim 1, wherein the movable sidewall is rectangular and has a perimeter that contacts areas adjacent an upper and a lower portion of, and areas adjacent a corner of, the chamber.

4. The chamber of claim 1, wherein the movable sidewall is rectangular and spans a length of the chamber.

5. The chamber of claim 1, further comprising:
at least one electron beam device coupled to the top.

6. The chamber of claim 1, wherein the at least one actuator moves the movable sidewall in a vertical direction between the open and the closed position.

7. The chamber of claim 1, further comprising:
a substrate support within the interior region.

8. The chamber of claim 1, further comprising:
a load lock chamber coupled to the at least one rigid sidewall.

9. The chamber of claim 1, wherein the movable sidewall is adapted to flex.

10. A testing table for supporting and transferring a large area substrate, the testing table comprising:
a segmented stage; and
an end effector integrated within the segmented stage, wherein the segmented stage is movable in a vertical direction and the end effector is movable in a first horizontal direction and wherein said stage and end effector are configured to support the large area substrate.

11. The testing table of claim 10, wherein the segmented stage includes a plurality of slots, each slot being configured to receive a finger of an end effector.

12. The testing table of claim 11, wherein the segmented stage and the finger in each of the plurality of slots are in the same horizontal plane during a testing sequence.

13. The testing table of claim 11, wherein the segmented stage and the finger in each of the plurality of slots are in a different horizontal plane during a transfer sequence.

14. The testing table of claim 10, wherein the segmented stage and the end effector each move independently and linearly in its respective direction.

15. The testing table of claim 10, wherein the end effector is adapted to extend in the horizontal direction from the segmented stage.

16. The testing table of claim 10, wherein the segmented stage is coupled to a first stage that moves in the first horizontal direction and a second stage that moves in a second horizontal direction.

17. A prober exchange apparatus, comprising:
an outer frame coupled to a first testing chamber;
an inner frame coupled to the outer frame, the inner frame comprising:
a plurality of transfer arms sized to receive at least one prober frame, wherein the inner frame is coupled to at least one actuator adapted to control the elevation of the inner frame and each of the transfer arms are movable relative the inner frame.

18. The apparatus of claim 17, wherein the transfer arms are adapted to move into and out of the first testing chamber laterally.

19. The apparatus of claim 17, wherein the first testing chamber includes a prober positioning assembly coupled to an upper surface of the first testing chamber.

20. The apparatus of claim 19, wherein the prober positioning assembly comprises at least two support members.

21. The apparatus of claim 17, wherein the at least two support members are adapted to selectively engage at least two prober support members coupled to the prober frame.

22. The apparatus of claim 17, wherein the first testing chamber is adapted to perform electron beam testing on large area substrates.

23. The apparatus of claim 17, wherein at least two transfer arms are capable of transferring probers in and out of the inner frame.

24. The apparatus of claim 17, further comprising;
a transfer apparatus disposed within and coupled to the first testing chamber, the transfer apparatus further comprising:
a mating mechanism adapted to engage and support a prober frame to facilitate transfer of one or more probers into and out of the first testing chamber.

25. The apparatus of claim 17, further comprising:
a prober storage assembly disposed beneath the first testing chamber, wherein at least two transfer arms are adapted to facilitate transfer of one or more probers into and out of the prober storage assembly.

26. The apparatus of claim 25, wherein the prober transfer assembly is arranged to transfer one or more probers between the prober storage assembly and the first testing chamber.

27. The apparatus of claim 17, further comprising:
a second testing chamber coupled to the outer frame.

28. A method of transferring one or more probers into and out of an electron beam testing chamber, comprising:
moving at least one prober from a prober storage assembly to a position supported by at least one transfer arm on a prober transfer assembly;
opening a prober transfer door coupled to the testing chamber;
extending the at least one transfer arm to insert the at least one prober into the testing chamber;
disengaging the at least one prober from the transfer arm;
engaging the at least one prober to a positioning device coupled to a substrate support table;
retracting the at least one transfer arm out of the testing chamber; and
closing the prober transfer door.
